(19) United States
(12) Patent Application Publication
(10) Pub. No.: US 2021/0183928 A1
(43) Pub. Date: Jun. 17, 2021

(54) IMAGING ELEMENT, METHOD OF MANUFACTURING THE SAME, AND ELECTRONIC APPLIANCE

(71) Applicant: SONY SEMICONDUCTOR SOLUTIONS CORPORATION, KANAGAWA (JP)

(72) Inventors: HIRONORI HOSHI, KANAGAWA (JP); KENICHI NISHIZAWA, TOKYO (JP); KIICHI ISHIKAWA, KANAGAWA (JP); RYOKO KAJIKAWA, KANAGAWA (JP)

(21) Appl. No.: 16/760,205

(22) PCT Filed: Oct. 25, 2018
(86) PCT No.: PCT/JP2018/039601

§ 371 Date: Apr. 29, 2020

(30) Foreign Application Priority Data
Nov. 8, 2017 (JP) 2017-215516

(51) Int. Cl. H01L 27/146

(52) U.S. Cl. CPC H01L 27/14621; H01L 27/14623; H01L 27/14685; H01L 27/14603; H01L 27/14627

(57) ABSTRACT

The present technology relates to an imaging element, a method of manufacturing the same, and an electronic appliance capable of reducing false signal output caused by reflected light of incident light. An imaging element includes: a semiconductor substrate including a photoelectric conversion unit for each pixel, the photoelectric conversion unit photoelectrically converting incident light; a color filter layer that is formed on the semiconductor substrate and that passes the incident light of a predetermined wavelength; a light-shielding wall that is formed at a pixel boundary on the semiconductor substrate so as to have a height greater than a height of the color filter layer; and a protective substrate that is disposed via a seal resin and that protects an upper-surface side of the color filter layer. The present technology can be applied to, for example, an imaging element having a CSP structure and the like.

### TECHNICAL FIELD

The present technology relates to an imaging element, a method of manufacturing the same, and an electronic appliance, and more particularly, to an imaging element, a method of manufacturing the same, and an electronic appliance capable of reducing false signal output caused by reflected light of incident light.

### BACKGROUND ART

A structure of a back-irradiation solid-state imaging apparatus is proposed. In the structure, a light-shielding wall is formed at a layer lower than a color filter layer to prevent incident light from going into an adjacent pixel (e.g., see Patent Document 1). Furthermore, the light-shielding wall is sometimes formed up to the height of the color filter layer (e.g., see Patent Document 2).

### CITATION LIST

### Patent Document

Patent Document 1: Japanese Patent Application Laid-Open No. 2013-251292
Patent Document 2: International Publication No. 2016/114154

### SUMMARY OF THE INVENTION

### Problems to be Solved by the Invention

Unfortunately, incident light is sometimes reflected on the surface of a semiconductor substrate or the surface of an on-chip lens (OCL), is re-reflected on a cover glass or an IR cut filter disposed on the upper side, and is then incident to a solid-state imaging apparatus again. Further ingenuity is needed for reducing false signal output called a flare and ghost.

The present technology has been made in view of such a situation, and can reduce the false signal output caused by reflected light of incident light.

### Solutions to Problems

An imaging element of a first aspect of the present technology includes: a semiconductor substrate including a photoelectric conversion unit for each pixel, the photoelectric conversion unit photoelectrically converting incident light; a color filter layer that is formed on the semiconductor substrate and that passes the incident light of a predetermined wavelength; a light-shielding wall that is formed at a pixel boundary on the semiconductor substrate so as to have a height greater than a height of the color filter layer; and a protective substrate that is disposed via a seal resin and that protects an upper-surface side of the color filter layer.

A method of manufacturing an imaging element of a second aspect of the present technology includes: forming a color filter layer that passes incident light of a predetermined wavelength on a semiconductor substrate including a photoelectric conversion unit for each pixel, the photoelectric conversion unit photoelectrically converting the incident light; forming a light-shielding wall having a height greater than a height of the color filter layer at a pixel boundary on the semiconductor substrate; and bonding a protective substrate on an upper side of the color filter layer via a seal resin.

An electronic appliance of a third aspect of the present technology includes an imaging element including: a semiconductor substrate including a photoelectric conversion unit for each pixel, the photoelectric conversion unit photoelectrically converting incident light; a color filter layer that is formed on the semiconductor substrate and that passes the incident light of a predetermined wavelength; a light-shielding wall that is formed at a pixel boundary on the semiconductor substrate so as to have a height greater than a height of the color filter layer; and a protective substrate that is disposed via a seal resin and that protects an upper-surface side of the color filter layer.

In the first to third aspects of the present technology, a color filter layer that passes incident light of a predetermined wavelength is formed on a semiconductor substrate including a photoelectric conversion unit for each pixel, the photoelectric conversion unit photoelectrically converting the incident light, a light-shielding wall having a height greater than a height of the color filter layer is formed at a pixel boundary on the semiconductor substrate, and a protective substrate is bonded on an upper side of the color filter layer via a seal resin.

The imaging element and the electronic appliance may be independent apparatus, or may be a module incorporated in another apparatus.

### Effects of the Invention

According to the first to third aspects of the present technology, false signal output caused by reflected light of incident light can be reduced.

Note that the effects described here are not necessarily limitative, and any of the effects described in the present disclosure may be exhibited.

### BRIEF DESCRIPTION OF DRAWINGS

FIG. 1 is a cross-sectional view of an imaging element as an embodiment to which the present technology is applied.

FIG. 2 is a cross-sectional view illustrating a first configuration example of the imaging element in FIG. 1.

FIG. 3 illustrates an effect in a case where the present technology is applied.

FIG. 4 illustrates a manufacturing method in the first configuration example.

FIG. 5 illustrates the manufacturing method in the first configuration example.

FIG. 6 illustrates disposition in a case where exit pupil correction is performed.

FIG. 7 is a cross-sectional view illustrating a first variation of the first configuration example.

FIG. 8 is a cross-sectional view illustrating a second variation of the first configuration example.

FIG. 9 is a cross-sectional view illustrating a second configuration example of the imaging element in FIG. 1.

FIG. 10 illustrates an effect of wavy structure.

FIG. 11 illustrates an effect of the wavy structure.

FIG. 12 illustrates a method of forming the wavy structure of a light-shielding wall.

FIG. 13 illustrates a manufacturing method in the second configuration example.

FIG. 14 illustrates the manufacturing method in the second configuration example.

FIG. 15 is a plan view illustrating a first variation of the second configuration example.

FIG. 16 illustrates an effect of the first variation of the second configuration example.

FIG. 17 illustrates a forming method in the first variation of the second configuration example.

FIG. 18 is a plan view illustrating a second variation of the second configuration example.

FIG. 19 illustrates a forming method in the second variation of the second configuration example.

FIG. 20 is a plan view illustrating the first variation of the second configuration example and another example of the second variation.

FIG. 21 is a cross-sectional view illustrating a third configuration example of the imaging element in FIG. 1.

FIG. 22 illustrates a manufacturing method in the third configuration example.

FIG. 23 illustrates the manufacturing method in the third configuration example.

FIG. 24 is a cross-sectional view illustrating a first variation of the third configuration example.

FIG. 25 is a cross-sectional view illustrating a second variation of the third configuration example.

FIG. 26 is a cross-sectional view illustrating a fourth configuration example of the imaging element in FIG. 1.

FIG. 27 illustrates a manufacturing method in the fourth configuration example.

FIG. 28 illustrates the manufacturing method in the fourth configuration example.

FIG. 29 illustrates the manufacturing method in the fourth configuration example.

FIG. 30 is a cross-sectional view illustrating a fifth configuration example of the imaging element in FIG. 1.

FIG. 31 is a cross-sectional view illustrating a first variation of the fifth configuration example.

FIG. 32 is a cross-sectional view illustrating a second variation of the fifth configuration example.

FIG. 33 is a cross-sectional view illustrating a third variation of the fifth configuration example.

FIG. 34 is a cross-sectional view illustrating a fourth variation of the fifth configuration example.

FIG. 35 illustrates a set value of the height of a light-shielding wall.

FIG. 36 illustrates oblique incidence characteristics.

FIG. 37 illustrates the relationship between a pixel size and a protrusion amount.

FIG. 38 is a cross-sectional view illustrating a variation of the light-shielding wall.

FIG. 39 outlines a configuration example of a laminated solid-state imaging apparatus to which the technology according to the disclosure can be applied.

FIG. 40 is a cross-sectional view illustrating a first configuration example of a laminated solid-state imaging apparatus 23020.

FIG. 41 is a cross-sectional view illustrating a second configuration example of the laminated solid-state imaging apparatus 23020.

FIG. 42 is a cross-sectional view illustrating a third configuration example of the laminated solid-state imaging apparatus 23020.

FIG. 43 is a cross-sectional view illustrating another configuration example of the laminated solid-state imaging apparatus to which the technology according to the disclosure can be applied.

FIG. 44 is a block diagram illustrating a configuration example of an imaging apparatus serving as an electronic appliance to which the present technology is applied.

FIG. 45 illustrates a usage example of an image sensor.

FIG. 46 is a block diagram illustrating one example of the schematic configuration of an in-vivo information acquisition system.

FIG. 47 illustrates one example of the schematic configuration of an endoscopic surgical system.

FIG. 48 is a block diagram illustrating examples of the functional configurations of a camera head and a CCU.

FIG. 49 is a block diagram illustrating one example of the schematic configuration of a vehicle control system.

FIG. 50 is an explanatory view illustrating examples of installation positions of a vehicle outside information detection portion and an imaging unit.

### MODE FOR CARRYING OUT THE INVENTION

An embodiment for carrying out the present technology (hereinafter referred to as an embodiment) will be described below. Note that the description will be given in the following order.

1. Cross-sectional View of Entire Imaging Element

2. First Configuration Example of Imaging Element

3. Manufacturing Method in First Configuration Example

4. First Variation of First Configuration Example

5. Second Variation of First Configuration Example

6. Second Configuration Example of Imaging Element

7. Manufacturing Method in Second Configuration Example

8. First Variation of Second Configuration Example

9. Second Variation of Second Configuration Example

10. Third Configuration Example of Imaging Element

11. Manufacturing Method in Third Configuration Example

12. First Variation of Third Configuration Example

13. Second Variation of Third Configuration Example

14. Fourth Configuration Example of Imaging Element

15. Manufacturing Method in Fourth Configuration Example

16. Fifth Configuration Example of Imaging Element

17. Height of Light-Shielding Wall

18. Conclusion

19. Configuration Example of Solid-State Imaging Apparatus Applicable as Imaging Substrate

20. Example of Application to Electronic Appliance

21. Usage Example of Image Sensor

22. Example of Application to In-Vivo Information Acquisition System

23. Example of Application to Endoscopic Surgical System

24. Example of Application to Moving Object

### 1. Cross-sectional View of Entire Imaging Element

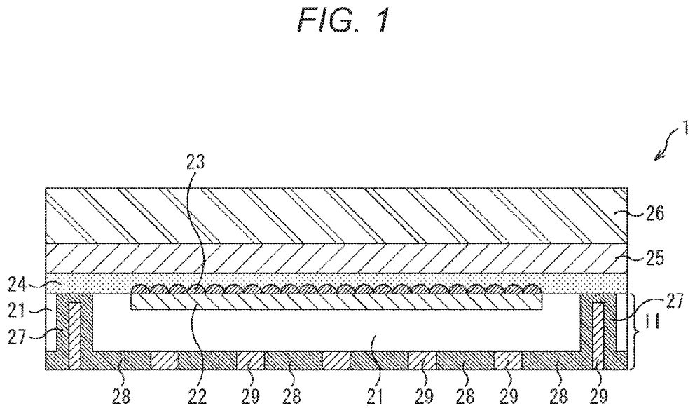

FIG. 1 is a cross-sectional view of an imaging element as an embodiment to which the present technology is applied.

An imaging element 1 illustrated in FIG. 1 includes a chip-sized imaging substrate 11. The imaging substrate 11 generates and outputs an imaging signal by photoelectrically converting incident light. The imaging element 1 has a chip size package (CSP) structure in which a cover glass 26 protects the upper-surface side that is a light incident surface of the imaging substrate 11. In FIG. 1, light is incident downward from the upper side of the cover glass 26, and the imaging substrate 11 receives the light.

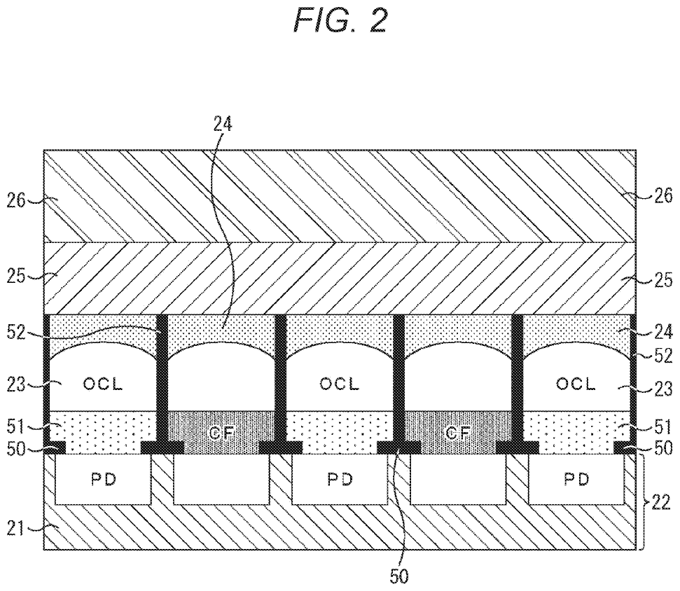

A photoelectric conversion region 22 is formed on a surface on the side of the cover glass 26 on the imaging substrate 11. The surface corresponds to the upper surface of a semiconductor substrate 21 including, for example, a silicon substrate. A photodiode PD (FIG. 2) is formed for each pixel in the photoelectric conversion region 22. The photodiode PD is a photoelectric conversion unit that photoelectrically converts incident light. Each pixel is two-dimensionally disposed in a matrix. An on-chip lens 23 is formed on a pixel basis on the upper surface of the semiconductor substrate 21. The photoelectric conversion region 22 is formed on the upper surface. A flattening film 24 is formed on the upper side of the on-chip lens 23. The cover glass 26 is bonded to the upper surface of the flattening film 24 via a glass seal resin 25.

An imaging signal generated at the photoelectric conversion region 22 of the imaging substrate 11 is output from a through electrode 27 and rewiring 28. The through electrode 27 penetrates the semiconductor substrate 21. The rewiring 28 is formed on the lower surface of the semiconductor substrate 21. A solder resist 29 covers a lower-surface region of the semiconductor substrate 21 other than a terminal unit including the through electrode 27 and the rewiring 28.

Note that, although not illustrated, a plurality of pixel transistors and a multilayer wiring layer are formed on the lower-surface side of the semiconductor substrate 21. The rewiring 28 is formed on the lower-surface side. The pixel transistors, for example, read a charge accumulated in the photodiode PD. The multilayer wiring layer includes a plurality of wiring layers and an interlayer insulating film. Consequently, the imaging element 1 in FIG. 1 is a back-irradiation light receiving sensor that photoelectrically converts light incident from the back-surface side opposite to the front-surface side of the semiconductor substrate 21. The multilayer wiring layer is formed on the front-surface side.

The terminal unit of the imaging substrate 11 is connected to a main substrate or an interposer substrate by, for example, a solder ball. The terminal unit includes the through electrode 27 and the rewiring 28. The imaging element 1 is mounted in the main substrate.

The imaging element 1 configured as described above is a chip size package (CSP) of structure without a cavity. The structure has no void between the cover glass 26 and the imaging substrate 11. The cover glass 26 protects the light incident surface (upper surface) of the imaging substrate 11. For example, the flattening film 24 and the glass seal resin 25 fill the space between the cover glass 26 and the imaging substrate 11.

Note that, although, in the embodiment, an example in which the cover glass 26 is used as a protective substrate for protecting the upper-surface side of the semiconductor substrate 21 will be described, for example, a light-transmitting resin substrate may be used instead of the cover glass 26.

### 2. First Configuration Example of Imaging Element

FIG. 2 is a cross-sectional view illustrating a detailed first configuration example of the imaging element 1 in FIG. 1.

FIG. 2 illustrates a detailed configuration example of an upper part from the photoelectric conversion region 22 in FIG. 1.

In the photoelectric conversion region 22 of the semiconductor substrate 21, a photodiode PD is formed for each pixel by, for example, forming an n-type (second conductive type) semiconductor region in a p-type (first conductive type) semiconductor region for each pixel. The photodiode PD is a photoelectric conversion unit that photoelectrically converts incident light.

An inter-pixel light-shielding film 50 is formed at a pixel boundary on the semiconductor substrate 21. The inter-pixel light-shielding film 50 is only required to include a material that blocks light. For example, metal material such as aluminum (Al), tungsten (W), and copper (Cu) can be adopted as material having a strong light-shielding property and capable of being processed with good precision by microfabrication, for example, etching. Furthermore, a photosensitive (light-absorbing) resin containing a carbon black pigment and a titanium black pigment may be used as a material of the inter-pixel light-shielding film 50.

A color filter layer (hereinafter referred to as a CF layer) 51 is formed for each pixel above the photodiode PD on the semiconductor substrate 21. The inter-pixel light-shielding film 50 is not performed on the semiconductor substrate 21. The CF layer 51 allows passage of incident light having a wavelength of red (R), green (G), or blue (B). Although, colors of R, G, and B are disposed in, for example, a Bayer array in the CF layer 51, other complementary colors, such as cyan (Cy), magenta (Mg), and yellow (Ye), and arrangement methods, such as a transparent (clear) filter, may be used.

Note that an anti-reflection film may be formed on an interface on the back-surface side (upper side in the figure) of the semiconductor substrate 21, and the inter-pixel light-shielding film 50 and the CF layer 51 may be formed on the anti-reflection film. The anti-reflection film includes, for example, a laminated film of a hafnium oxide (HfO2) layer and a silicon oxide layer.

The on-chip lens (hereinafter referred to as the OCL) 23 is formed for each pixel on the CF layer 51. The flattening film 24 is formed on the OCL 23. The flattening film 24 is a light-transmitting layer that allows passage of incident light.

Furthermore, a light-shielding wall 52 is formed at a pixel boundary on the upper surface of the inter-pixel light-shielding film 50. The light-shielding wall 52 separates the CF layer 51, the OCL 23, and the flattening film 24 on a pixel basis. In a similar manner to the inter-pixel light-shielding film 50, a material of the light-shielding wall 52 can include metal material and a photosensitive (light-absorbing) resin. The metal material includes, for example, aluminum (Al) and tungsten (W). The photosensitive resin contains a carbon black pigment and a titanium black pigment. The light-shielding wall 52 is formed from the upper surface of the inter-pixel light-shielding film 50 to the same height as that of the flattening film 24. Then, the glass seal resin 25 and the cover glass 26 are formed in the order on the light-shielding wall 52 and the flattening film 24. The glass seal resin 25 is transparent, and joins the cover glass 26 to the imaging substrate 11 without a cavity.

For example, an organic material and an inorganic material are used as a material of the OCL 23 and the flattening film 24. The organic material includes, for example, a styrene resin, an acrylic resin, a styrene-acrylic copolymer resin, and a siloxane resin. The inorganic material includes, for example, SiN and SiON. A material of each of the OCL 23 and the flattening film 24 is selected such that the flattening film 24 has a refractive index lower than that of the OCL 23. For example, the styrene resin has a refractive index of approximately 1.6. The acrylic resin has a refractive index of approximately 1.5. The styrene-acrylic copolymer resin has a refractive index of approximately 1.5 to 1.6. The siloxane resin has a refractive index of approximately 1.45. SiN has a refractive index of approximately 1.9 to 2.0. SiON has a refractive index of 1.45 to 1.9. Furthermore, the refractive indices of the OCL 23 and the flattening film 24 are configured to be within a range of the refractive index of the cover glass 26 and the refractive index of the CF layer 51. The cover glass 26 has a refractive index of approximately 1.45. The CF layer 51 has a refractive index of 1.6 to 1.7.

As described above, the light-shielding wall 52 is formed up to the position of the flattening film 24 above the photodiode PD of the photoelectric conversion region 22. The light-shielding wall 52 is formed on the upper surface of the inter-pixel light-shielding film 50. The flattening film 24 is placed above the CF layer 51. Note that the inter-pixel light-shielding film 50 and the light-shielding wall 52 are omitted in the schematic view of the entire imaging element 1 in FIG. 1.

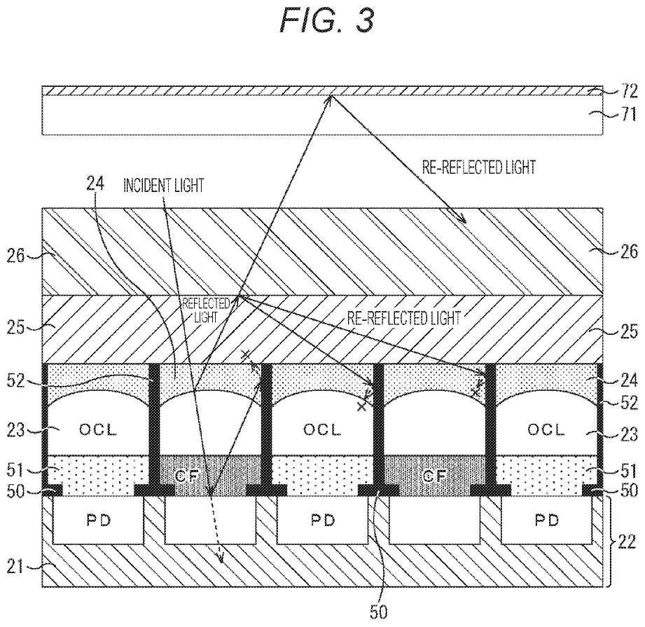

As illustrated in FIG. 3, in order to obtain incident light by cutting IR light, the imaging element 1 may have a configuration in which an IR cut filter 72 is disposed on the light incident side. The IR cut filter 72 is formed on a glass 71.

Incident light is reflected on an interface of the semiconductor substrate 21 and the surface of the OCL 23 to be reflected light. The reflected light is re-reflected at the IR cut filter 72 or the cover glass 26. In the above-described case, the re-reflected light is incident to the imaging element 1, and can cause a flare and ghost.

The imaging element 1 reflects or absorbs light that is re-reflected at the cover glass 26 or the IR cut filter 72 and is again incident to the imaging element 1 by the light-shielding wall 52 that is higher than the CF layer 51 and that is formed up to the position of the upper surface of the flattening film 24, so that the imaging element 1 can reduce false signal output called a flare and ghost. The imaging element 1 can be preferably used for, in particular, an apparatus that needs an imaging unit for receiving light having high intensity and being parallel, for example, an imaging unit and the like of an endoscope and a fundus examination apparatus.

### 3. Manufacturing Method in First Configuration Example

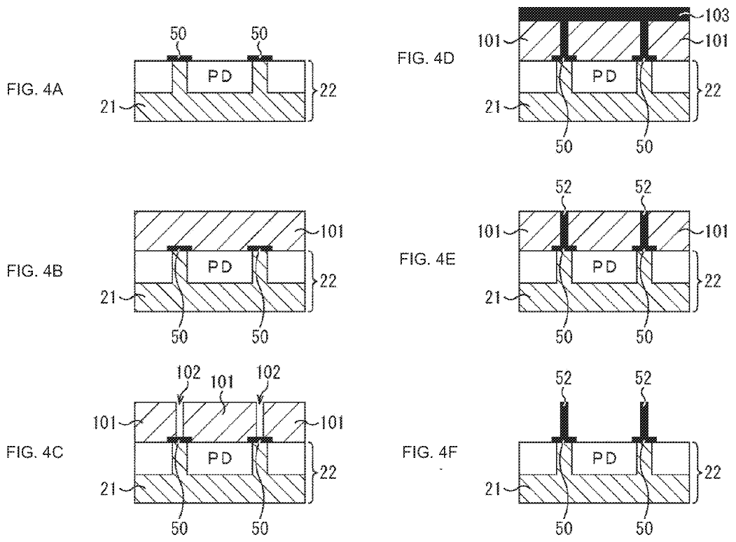

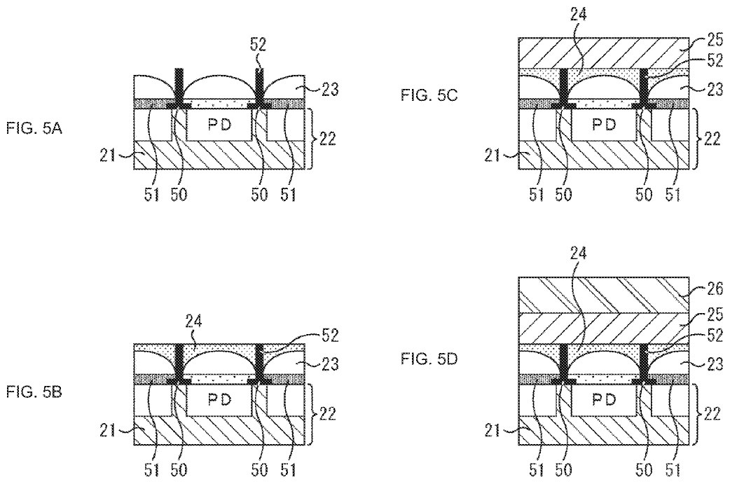

A method of manufacturing the imaging element 1 illustrated in FIG. 2 in a first configuration example will be described with reference to FIGS. 4 and 5.

First, as illustrated in A of FIG. 4, the inter-pixel light-shielding film 50 is formed on a pixel boundary part on the upper surface on the back-surface side of the semiconductor substrate 21. In the semiconductor substrate 21, the photodiode PD is formed on a pixel basis.

Note that, in the process before forming the inter-pixel light-shielding film 50, processes of forming a photodiode PD on a pixel basis on the back-surface side of the semiconductor substrate 21 and of forming a plurality of pixel transistors Tr and a multilayer wiring layer on the front-surface side of the semiconductor substrate 21 are performed. The transistors Tr read a charge accumulated in the photodiode PD, for example. The multilayer wiring layer includes a plurality of wiring layers and an interlayer insulating film. These processes are similar to those in a case of forming a common back-irradiation solid-state imaging element, and thus illustration and detailed description are omitted.

Next, as illustrated in B of FIG. 4, an insulating film 101 including, for example, SiO2 and the like is formed on the semiconductor substrate 21 including the inter-pixel light-shielding film 50, and a predetermined part of the inter-pixel light-shielding film 50 is etched. As a result, as illustrated in C of FIG. 4, an opening 102 is formed for the light-shielding wall 52 to be formed.

Then, as illustrated in D of FIG. 4, filling material 103 such as tungsten (W) fills the interior of the opening 102 by, for example, sputtering, and serves as a film on the upper surface of the insulating film 101. In a case where, for example, a photosensitive resin containing a carbon black pigment (hereinafter referred to as a carbon black resin) is used as a material of the light-shielding wall 52, the carbon black resin serving as the filling material 103 is formed in the interior of the opening 102 and on the upper surface of the insulating film 101 by spin coating.

Thereafter, as illustrated in E of FIG. 4, the filling material 103 formed on the upper surface of the insulating film 101 is removed by chemical mechanical polishing (CMP) to form the light-shielding wall 52. As illustrated in F of FIG. 4, the insulating film 101 is removed by, for example, wet etching.

Subsequently, as illustrated in A of FIG. 5, the CF layer 51 and the OCL 23 are formed on the upper surface of the photodiode PD. As illustrated in B of FIG. 5, the flattening film 24 is formed on the upper surface of the OCL 23 to have the same height as that of the light-shielding wall 52.

Finally, as illustrated in C and D of FIG. 5, the upper surfaces of the flattening film 24 and the light-shielding wall 52 are coated with the glass seal resin 25, and the cover glass 26 is joined to the glass seal resin 25.

The imaging element 1 according to the first configuration example can be manufactured as described above.

Note that, in the imaging element 1, for example, the inter-pixel light-shielding film 50, the CF layer 51, and the light-shielding wall 52, which are formed on the upper surface of the semiconductor substrate 21, can be disposed such that exit pupil correction is performed.

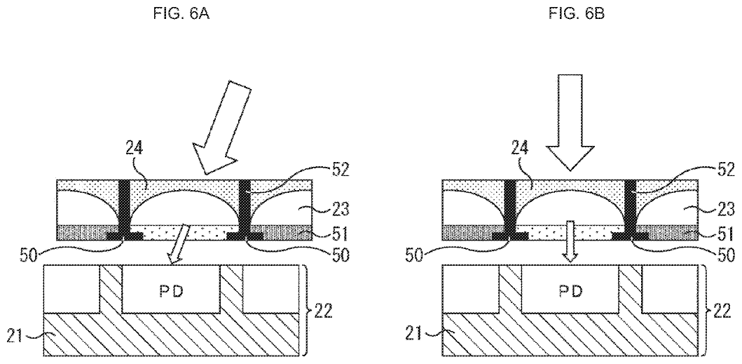

FIG. 6 illustrates disposition in a case where the imaging element 1 performs the exit pupil correction.

In a central region of a pixel array unit in which pixels are two-dimensionally disposed in a matrix, the incidence angle of a main light beam of incident light from an optical lens (not illustrated) is zero degrees, and thus the exit pupil correction is not performed. That is, as illustrated in B of FIG. 6, the CF layer 51, the OCL 23, and the flattening film 24, which are formed on the upper surface of the semiconductor substrate 21, are disposed so as to coincide with the center of the photodiode PD.

In contrast, in a region around the pixel array unit, the incidence angle of a main light beam of incident light from the optical lens is set to have a predetermined value in accordance with lens design, and thus the exit pupil correction is performed. That is, as illustrated in A of FIG. 6, the OCL 23, the flattening film 24, and the CF layer 51, which are formed on the upper surface of the semiconductor substrate 21, are disposed such that the centers of the OCL 23, the flattening film 24, and the CF layer 51 are shifted together with the light-shielding wall 52 from the center of the photodiode PD to the central side of the pixel array unit. This can further inhibit, for example, a reduction in sensitivity due to shading and leakage of incident light of an adjacent pixel in a pixel around the pixel array unit.

### 4. First Variation of First Configuration Example

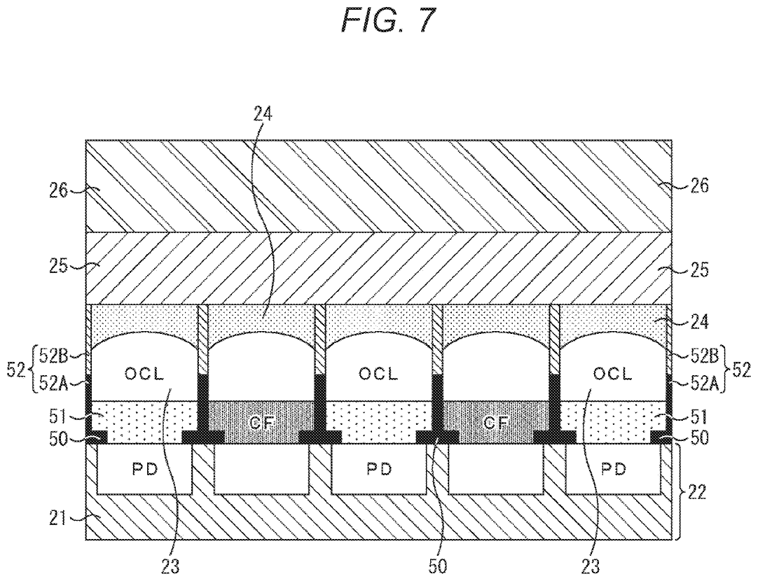

FIG. 7 illustrates a first variation of the first configuration example illustrated in FIG. 2.

In FIG. 7, the same signs are attached to the parts corresponding to those in FIG. 2, and the description of the parts will be appropriately omitted.

In the first configuration example illustrated in FIG. 2, the light-shielding wall 52 formed on the inter-pixel light-shielding film 50 includes one type of material including, for example, metal material such as tungsten (W) and a carbon black resin.

In contrast, in the first variation in FIG. 7, the light-shielding wall 52 includes materials different in the upper part and the lower part. For example, a light-shielding wall 52A includes metal material such as tungsten (W), and a light-shielding wall 52B includes a carbon black resin. The light-shielding wall 52A is a lower part of the light-shielding wall 52. The light-shielding wall 52B is an upper part of the light-shielding wall 52.

In this way, the light-shielding wall 52 can include materials different in the upper part and the lower part. Note that, although a carbon black resin may be used as material of the lower light-shielding wall 52A, and metal material such as tungsten (W) may be used as material of the upper light-shielding wall 52B, a light-absorbing resin is more preferably used for the upper part. Furthermore, the material is not limited to two types. Three or more types of materials may be separately used in a height direction to form the light-shielding wall 52.

### 5. Second Variation of First Configuration Example

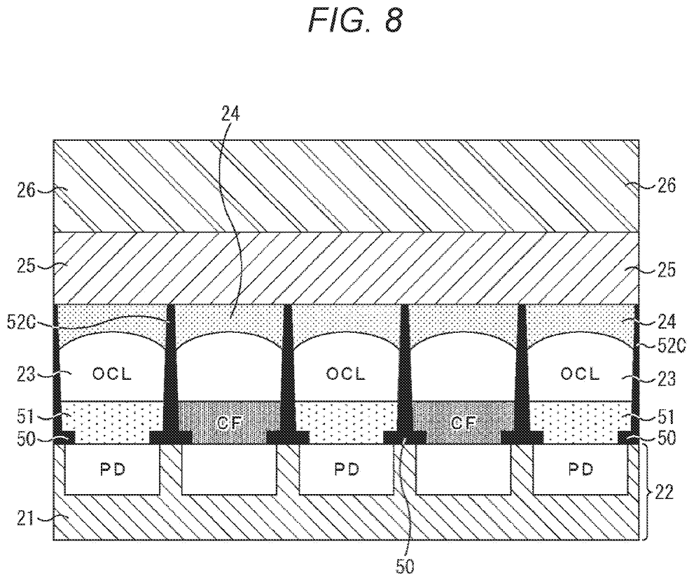

FIG. 8 illustrates a second variation of the first configuration example illustrated in FIG. 2.

In FIG. 8, the same signs are attached to the parts corresponding to those in FIG. 2, and the description of the parts will be appropriately omitted.

In FIG. 8, the light-shielding wall 52 in the first configuration example illustrated in FIG. 2 is replaced with a light-shielding wall 52C. Other configurations in FIG. 8 are similar to those in the first configuration example illustrated in FIG. 2.

The light-shielding wall 52 in the first configuration example illustrated in FIG. 2 has the same thickness (thickness in a plane direction) from the bottom surface on which the light-shielding wall 52 is in contact with the inter-pixel light-shielding film 50 to the upper surface on which the light-shielding wall 52 is in contact with the glass seal resin 25.

In contrast, in the second variation in FIG. 8, the light-shielding wall 52C has a tapered shape in which the side surface is inclined. The light-shielding wall 52C is thickest at the bottom surface on which the light-shielding wall 52C is in contact with the inter-pixel light-shielding film 50, and thinnest at the upper surface on which the light-shielding wall 52C is in contact with the glass seal resin 25. The light-shielding wall 52C in plan view has a rectangular shape. The opening area inside the light-shielding wall 52C is minimum at the bottom surface on the side of the CF layer 51, and maximum at the upper surface on the side of the glass seal resin 25.

In this way, the light-shielding wall 52C having a tapered side surface enables the photodiode PD to capture much incident light, and can improve sensitivity.

In relation to the tapered light-shielding wall 52C, the opening 102 can be tapered by controlling a dry etching condition at the time of forming the opening 102 in C of FIG. 4. The light-shielding wall 52C is tapered by filling the tapered opening 102 with the filling material 103.

Note that the light-shielding wall 52C may include one type of material including metal material such as tungsten (W) and a carbon black resin, or as in the first variation, two or more types of materials may be separately used in the height direction.

### 6. Second Configuration Example of Imaging Element

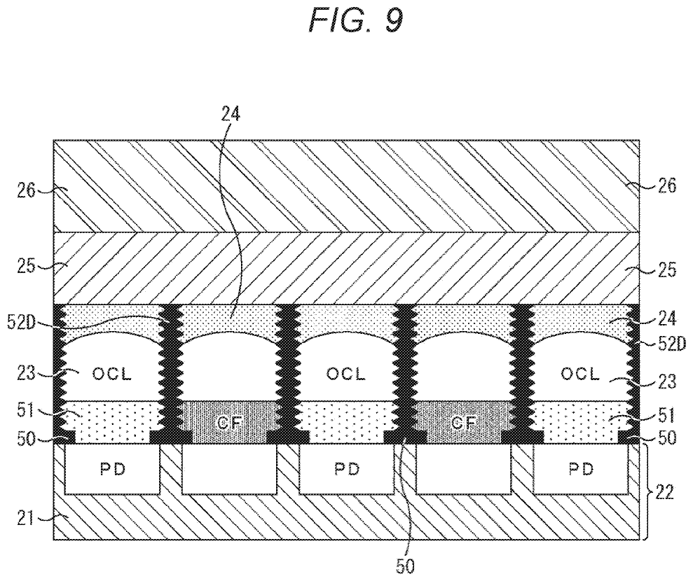

FIG. 9 is a cross-sectional view illustrating a detailed second configuration example of the imaging element 1 in FIG. 1.

In FIG. 9, the same signs are attached to the parts corresponding to those in FIG. 2, and the description of the parts will be appropriately omitted.

In FIG. 9, the light-shielding wall 52 in the first configuration example illustrated in FIG. 2 is replaced with a light-shielding wall 52D. Other configurations in FIG. 9 are similar to those in the first configuration example illustrated in FIG. 2.

While the light-shielding wall 52 in the first configuration example illustrated in FIG. 2 has a flat side surface without unevenness, the light-shielding wall 52D in FIG. 9 has a side surface that is wavy (uneven) in cross-sectional view.

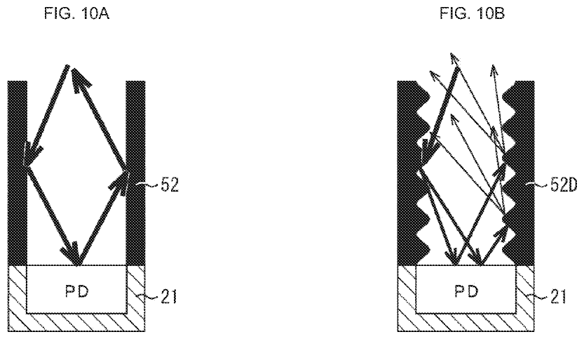

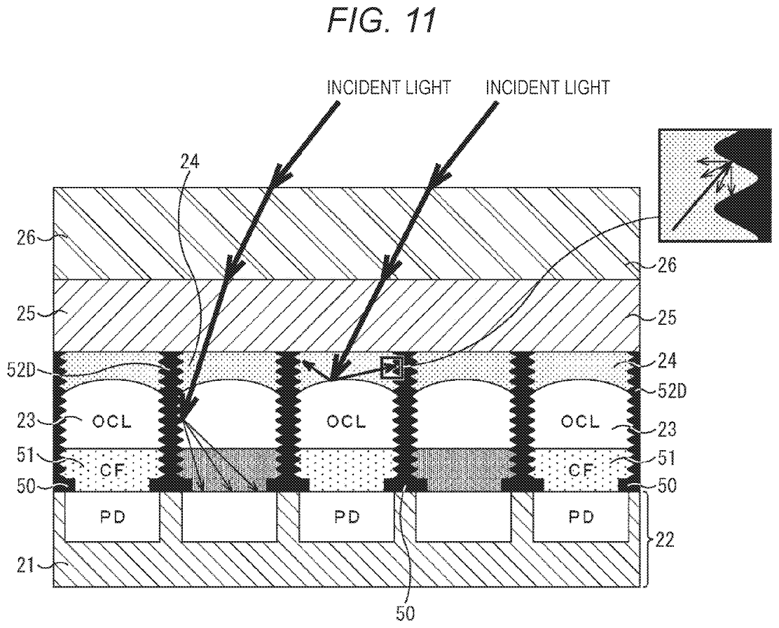

This causes light incident to the upper surface of the semiconductor substrate 21 to be dispersed and reflected as illustrated in B of FIG. 10, and thus the light intensity of reflected light is lowered in a case of the light-shielding wall 52D having a wavy side surface as compared to the case of the flat light-shielding wall 52 illustrated in A of FIG. 10. Furthermore, as illustrated in FIG. 11, light incident to the light-shielding wall 52 is also dispersed and reflected, so that the light intensity of reflected light is lowered.

Consequently, according to the imaging element 1 according to the second configuration example, false signal output called a flare and ghost can be further reduced.

### 7. Manufacturing Method in Second Configuration Example

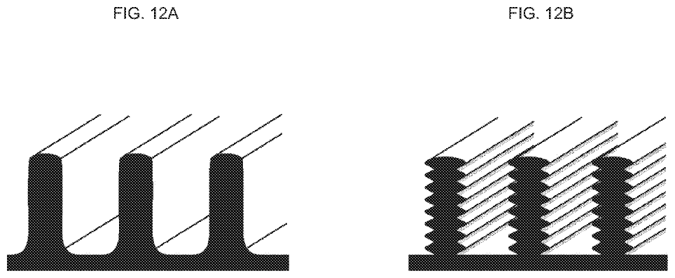

FIG. 12 illustrates a method of forming the wavy structure of the light-shielding wall 52D.

In a case of forming a shape of a light-shielding wall with a resist, usually, processing of inhibiting a reflected wave from the semiconductor substrate 21 is performed by coating the upper and lower surfaces of the resist with anti-reflective-coating (ARC) and bottom-anti-refrective-coating (BARC) in order to reduce standing waves. A of FIG. 12 illustrates the light-shielding wall shape of a resist formed by applying ARC and BRAC and inhibiting standing waves.

In contrast, in a case of forming the light-shielding wall 52D having a wavy structure, the ARC and BRAC do not dare to be applied, and a standing wave is used. This enables the light-shielding wall 52D to have a wall surface of a wavy structure as illustrated in B of FIG. 12.

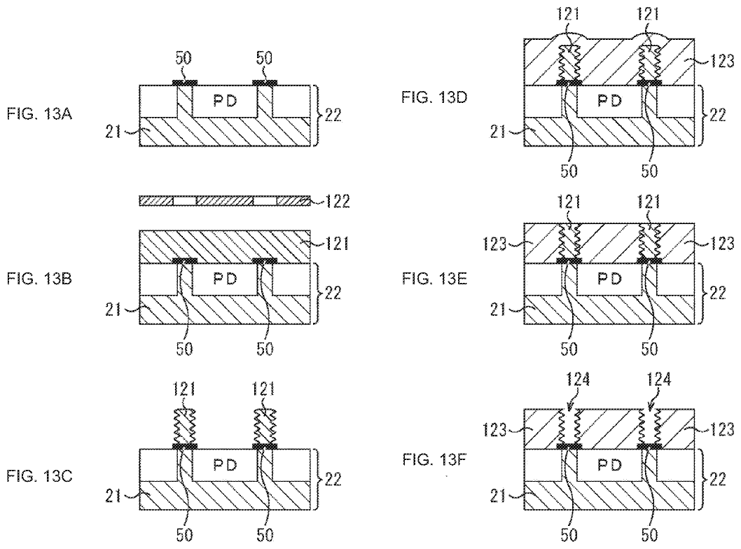

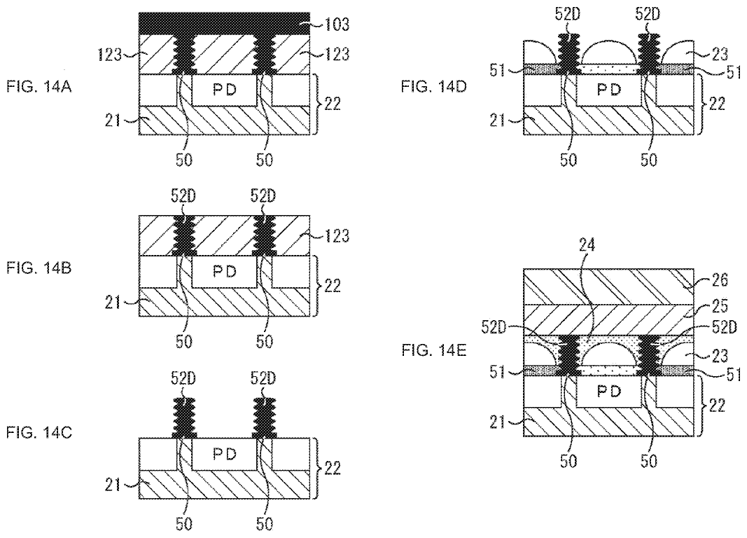

A method of manufacturing the imaging element 1 illustrated in FIG. 9 in the second configuration example will be described with reference to FIGS. 13 and 14.

In A of FIG. 13, in a manner similar to that in A of FIG. 4 in the first configuration example, the inter-pixel light-shielding film 50 is formed at a pixel boundary part of the upper surface on the back-surface side of the semiconductor substrate 21 in which, for example, the photodiode PD and the multilayer wiring layer are formed.

Next, as illustrated in B of FIG. 13, the upper surface on the back-surface side of the semiconductor substrate 21 is coated with a resist 121, and is exposed and developed with a mask 122 having a pattern corresponding to a position where the light-shielding wall 52D is formed, whereby the resist 121 at a position other than the position where the light-shielding wall 52D is formed is removed. In a case of applying the resist 121, as described in FIG. 12, the upper and lower surfaces do not dare to be coated with the ARC and BRAC. This causes the resist 121 after development to have the same wavy structure as the light-shielding wall 52D as illustrated in C of FIG. 13. For example, an organic material capable of withstanding a high temperature, such as “IX370G” manufactured by JSR Corporation can be used for the resist 121.

Note that the resist 121 having a wavy structure can be formed in a tapered shape with inclination by controlling a light application condition in a case of performing exposure with the mask 122. Consequently, the light-shielding wall 52D having a wavy structure can be formed in a tapered shape as in the second variation of the first configuration example.

Next, as illustrated in D of FIG. 13, an insulating film 123 is formed with a thickness equal to or greater than the height of the resist 121. The resist 121 is formed in a shape of a light-shielding wall. As illustrated in E of FIG. 13, the insulating film 123 is removed by CMP to the same height as that of the resist 121. A low temperature oxide (LTO) film capable of being formed at a low temperature can be used as the insulating film 123.

Next, as illustrated in F of FIG. 13, the resist 121 formed in the shape of a light-shielding wall is peeled off to form an opening 124 in the insulating film 123.

The state of F of FIG. 13 is the same as that in C of FIG. 4 described in the manufacturing method in the first configuration example, except that the opening 124 has a wavy side surface. Subsequent processes are similar to those in the manufacturing method in the first configuration example.

That is, as illustrated in A of FIG. 14, the filling material 103 such as tungsten (W) fills the interior of the opening 124, and serves as a film on the upper surface of the insulating film 123.

Then, as illustrated in B of FIG. 14, the filling material 103 formed on the upper surface of the insulating film 123 is removed by CMP to form the light-shielding wall 52D. As illustrated in C of FIG. 14, the insulating film 123 is removed by, for example, wet etching.

Subsequently, as illustrated in D of FIG. 14, the CF layer 51 and the OCL 23 are formed on the upper surface of the photodiode PD. As illustrated in E of FIG. 14, the flattening film 24, the glass seal resin 25, and the cover glass 26 are formed.

### 8. First Variation of Second Configuration Example

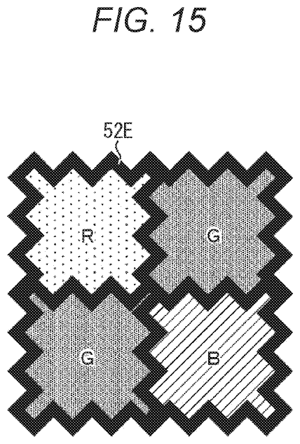

FIG. 15 illustrates a first variation of the second configuration example illustrated in FIG. 9.

Although the light-shielding wall 52D has a wavy side surface in cross-sectional view in the above-described second configuration example, as illustrated in FIG. 15, a light-shielding wall 52E may have a wavy (sawtooth) side surface in plan view.

FIG. 15 is a plan view illustrating the CF layer 51 and the light-shielding wall 52E of the imaging element 1 according to the first variation of the second configuration example in 2×2=four-pixel regions.

In FIG. 15, the light-shielding wall 52E has a sawtooth side surface in plan view, and each color of the CF layer 51 is disposed in a Bayer array.

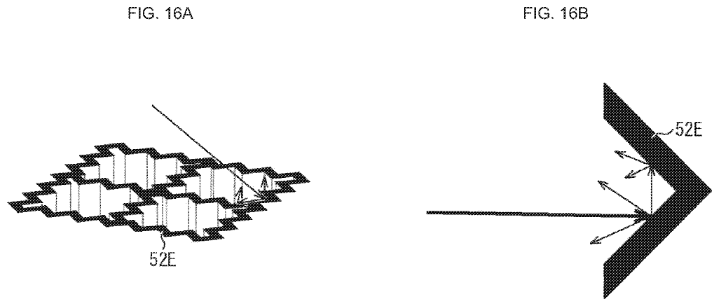

In this way, effects similar to those of the light-shielding wall 52D can be exhibited by the light-shielding wall 52E having the sawtooth side surface in plan view. That is, as illustrated in FIG. 16, light incident to the light-shielding wall 52E is dispersed and reflected, so that the light intensity of the reflected light can be lowered. This can reduce false signal output called a flare and ghost.

A of FIG. 16 is a conceptual view illustrating how incident light is reflected on the light-shielding wall 52E, which is illustrated in a perspective view. B of FIG. 16 is a conceptual view illustrating how incident light is reflected on one recess of the light-shielding wall 52E, which is enlarged in a plan view.

Note that the light-shielding wall 52E may have a sawtooth side surface in plan view as illustrated in FIGS. 15 and 16, or may have a side surface having a wavy shape in which a corner of a change point of unevenness is rounded. The wavy shape includes a sawtooth shape.

A method of forming the light-shielding wall 52E having a wavy (sawtooth) shape in plan view illustrated in FIG. 15 will be described.

In the process, described in B and C of FIG. 13, of exposing and developing the resist 121 with the mask 122 and forming a pattern in the shape of the light-shielding wall 52D, the light-shielding wall 52E

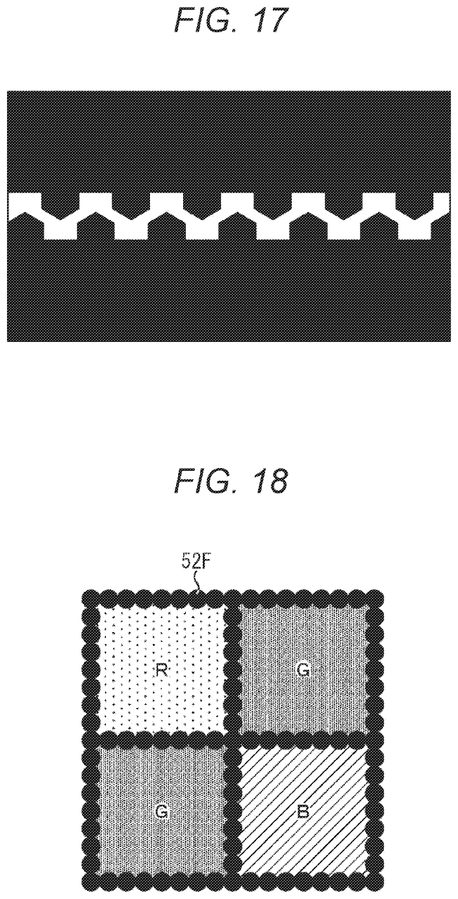

having a wavy shape in plan view can be formed by making a pattern of the mask 122 in the same uneven shape as that of the plane pattern of the light-shielding wall 52E illustrated in FIG. 15. Alternatively, the pattern of the mask 122 may be a plane pattern on which optical proximity correction (OPC) is performed as illustrated in FIG. 17.

### 9. Second Variation of Second Configuration Example

FIG. 18 illustrates a second variation of the second configuration example illustrated in FIG. 9.

Although the light-shielding wall 52E has a wavy side surface in plan view in the first variation in FIG. 15, as illustrated in FIG. 18, a light-shielding wall 52F may have a side surface having a repeated-arc shape.

FIG. 18 is a plan view illustrating the CF layer 51 and the light-shielding wall 52F of the imaging element 1 according to the second variation of the second configuration example in 2×2=four-pixel regions.

In FIG. 18, the light-shielding wall 52F has a side surface with a repeated-arc shape in plan view, and each color of the CF layer 51 is disposed in a Bayer array.

In this way, effects similar to those of the light-shielding wall 52E can be exhibited by the light-shielding wall 52F having the side surface with the repeated-arc shape in plan view. That is, light incident to the light-shielding wall 52F is dispersed and reflected, so that the light intensity of the reflected light can be lowered. This can reduce false signal output called a flare and ghost.

Note that, although FIG. 18 illustrates an example of the light-shielding wall 52F having repeated projecting arcs inside a pixel, the light-shielding wall 52F may have repeated projecting arcs outside the pixel. The wavy shape includes the repeated-arc shape.

A method of forming the light-shielding wall 52F having the repeated-arc shape in plan view illustrated in FIG. 18 will be described.

In the process, described in B and C of FIG. 13, of exposing and developing the resist 121 with the mask 122 and forming a pattern in the shape of the light-shielding wall 52D, a binary mask is usually used as the mask 122. In order to form the repeated-arc shape in FIG. 18, however, a halftone mask (phase difference shift mask) is used.

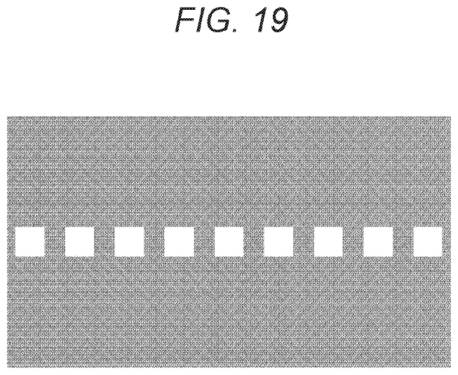

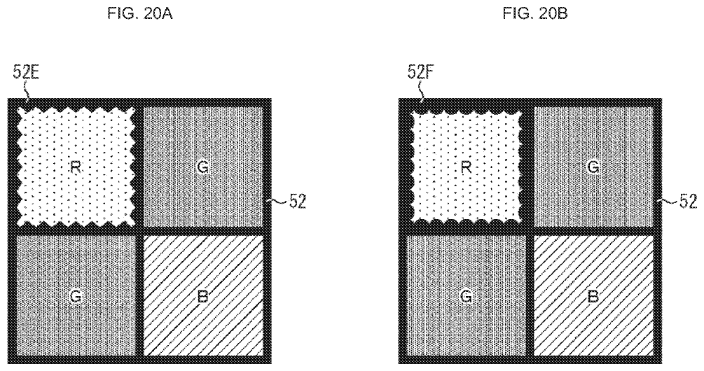

Specifically, the light-shielding wall 52F having the repeated-arc shape in plan view can be formed by performing exposure and development with a halftone mask as illustrated in FIG. 19. In the halftone mask, a pattern is formed. In the pattern, rectangular openings are arranged at a predetermined pitch in accordance with the positions where the light-shielding walls 52F are formed.

As described above, as in the first and second variations of the second configuration example, the light-shielding wall 52 having an uneven shape in plan view can reduce false signal output called a flare and ghost.

Note that, in a case of forming the light-shielding wall 52E having a wavy shape in plan view and the light-shielding wall 52F having a repeated-arc shape, if ARC and BARC are applied and reflected wave from the semiconductor substrate 21 is inhibited in the processes, corresponding to B and C in FIG. 13, of exposure and development, the light-shielding wall 52 having an uneven shape only in plan view can be formed. If ARC and BARC are not applied and a standing wave is used, the light-shielding wall 52 having an uneven shape in cross-sectional view and an uneven shape in plan view can be formed.

Although, in the examples illustrated in FIGS. 15 and 18, all pixels disposed in a Bayer array have a wavy or repeated-arc shape in plan view, only an R pixel among the R pixel, a G pixel, and a B pixel may has a wavy or repeated-arc shape in plan view as illustrated in A and B of FIG. 20. The R pixel receives light of R. The G pixel receives light of G. The B pixel receives light of B. The R pixel receives light having the longest wavelength.

A of FIG. 20 is a plan view illustrating the light-shielding wall 52E obtained by forming the light-shielding wall 52 in a sawtooth shape in plan view for only the R pixel.

B of FIG. 20 is a plan view illustrating the light-shielding wall 52F obtained by forming the light-shielding wall 52 in a repeated-arc shape in plan view for only the R pixel.

### 10. Third Configuration Example of Imaging Element

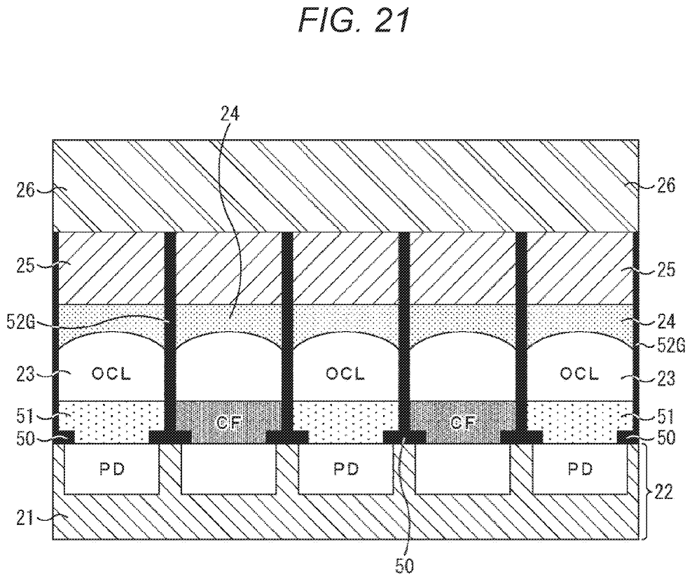

FIG. 21 is a cross-sectional view illustrating a detailed third configuration example of the imaging element 1 in FIG. 1.

In FIG. 21, the same signs are attached to the parts corresponding to those in FIG. 2, and the description of the parts will be appropriately omitted.

In FIG. 21, the light-shielding wall 52 in the first configuration example illustrated in FIG. 2 is replaced with a light-shielding wall 52G. Other configurations in FIG. 21 are similar to those in the first configuration example illustrated in FIG. 2.

The light-shielding wall 52 in the first configuration example illustrated in FIG. 2 has a height from the CF layer 51 to the upper surface of the flattening film 24, that is, to the glass seal resin 25. In contrast, the light-shielding wall 52G in the third configuration example in FIG. 21 has a height from the CF layer 51 to the upper surface of the glass seal resin 25, that is, to the cover glass 26.

This can further inhibit re-reflected light caused by reflected light of incident light re-reflecting on the IR cut filter 72 (FIG. 3) or the cover glass 26 from being incident to the imaging element 1, and reduce false signal output called a flare and ghost.

In a manner similar to that in the above-described first configuration example, a material of the light-shielding wall 52G can include metal material and a photosensitive resin. The metal material includes, for example, aluminum (Al) and tungsten (W). The photosensitive resin contains a carbon black pigment and a titanium black pigment.

### 11. Manufacturing Method in Third Configuration Example

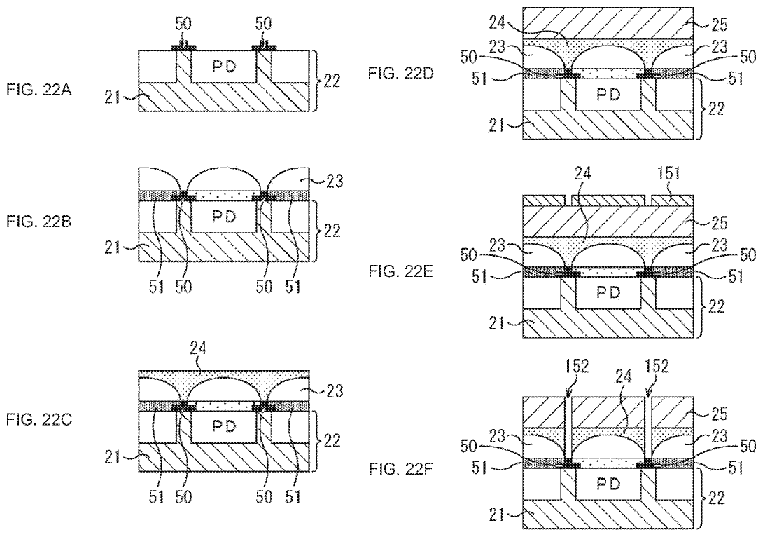

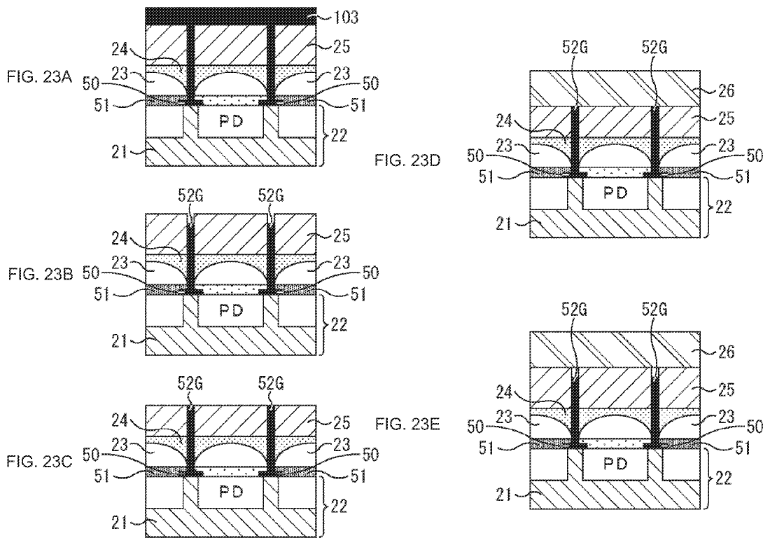

A method of manufacturing the imaging element 1 illustrated in FIG. 21 in the third configuration example will be described with reference to FIGS. 22 and 23.

In A of FIG. 22, in a manner similar to that in A of FIG. 4 in the first configuration example, the inter-pixel light-shielding film 50 is formed at a pixel boundary part of the upper surface on the back-surface side of the semiconductor substrate 21 in which, for example, the photodiode PD and the multilayer wiring layer are formed.

Next, as illustrated in B of FIG. 22, the CF layer 51 and the OCL 23 are formed on the upper surface of the photodiode PD. As illustrated in C of FIG. 22, the flattening film 24 is formed on the upper surface of the OCL 23.

Subsequently, as illustrated in D of FIG. 22, the upper surfaces of the flattening film 24 and the light-shielding wall 52 are coated with the glass seal resin 25. As illustrated in E of FIG. 22, the upper surface of the glass seal resin 25 is coated with a resist 151, and patterned in accordance with the position where the light-shielding wall 52G is formed.

Then, as illustrated in F of FIG. 22, an opening 152 is formed for the light-shielding wall 52G to be formed by etching the glass seal resin 25 and the flattening film 24 until the inter-pixel light-shielding film 50 is exposed on the basis of the patterned resist 151.

Then, as illustrated in A of FIG. 23, the filling material 103 such as tungsten and a carbon black resin fills the interior of the opening 152, and serves as a film on the upper surface of the glass seal resin 25.

Next, as illustrated in B of FIG. 23, the light-shielding wall 52G is formed by removing the filling material 103 formed on the upper surface of the glass seal resin 25 by, for example, dry etching. In the state, the light-shielding wall 52G has a height slightly lower than that of the glass seal resin 25.

As illustrated in C of FIG. 23, the glass seal resin 25 is scraped by, for example, CMP to align the height of the glass seal resin 25 and that of the light-shielding wall 52G. As illustrated in D of FIG. 23, the cover glass 26 is bonded. The imaging element 1 according to the third configuration example is completed.

Note that, as illustrated in E of FIG. 23, the cover glass 26 may be bonded with the height of the light-shielding wall 52G being lower than that of the glass seal resin 25.

In the imaging element 1 according to the third configuration example as well, the OCL 23, the flattening film 24, and the CF layer 51 are disposed such that the centers of the OCL 23, the flattening film 24, and the CF layer 51 are shifted together with the light-shielding wall 52 from the center of the photodiode PD to the central side of the pixel array unit in a region around the pixel array unit. This enables exit pupil correction.

### 12. First Variation of Third Configuration Example

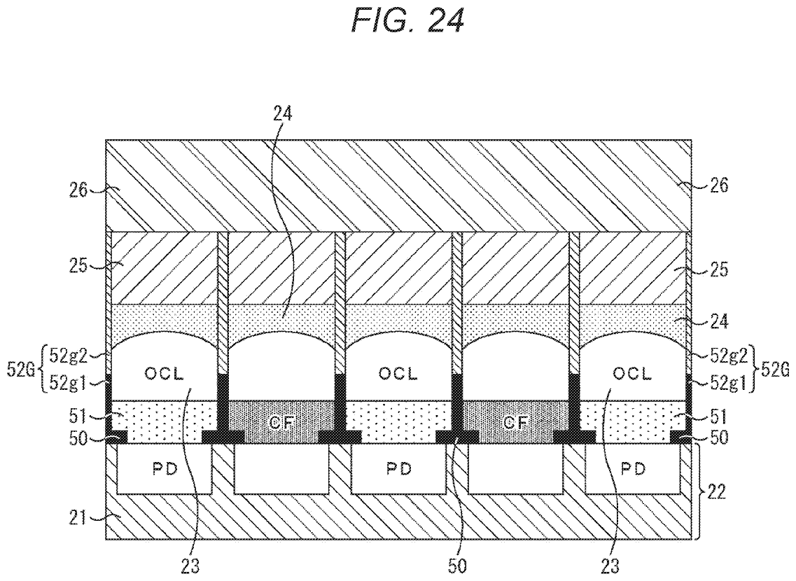

FIG. 24 illustrates a first variation of the third configuration example illustrated in FIG. 21.

In FIG. 24, the same signs are attached to the parts corresponding to those in FIG. 21, and the description of the parts will be appropriately omitted.

In the third configuration example illustrated in FIG. 21, the light-shielding wall 52G formed on the inter-pixel light-shielding film 50 include one type of material including, for example, metal material such as tungsten (W) and a carbon black resin.

In contrast, in the first variation in FIG. 24, the light-shielding wall 52G includes materials different in the upper part and the lower part. For example, a light-shielding wall 52g1 includes metal material such as tungsten (W), and a light-shielding wall 52g2 includes a carbon black resin. The light-shielding wall 52g1 is a lower part of the light-shielding wall 52G. The light-shielding wall 52g2 is an upper part of the light-shielding wall 52G.

In this way, the light-shielding wall 52G can include materials different in the upper part and the lower part. Note that, although a carbon black resin may be used as material of the lower light-shielding wall 52g1, and metal material such as tungsten (W) may be used as material of the upper light-shielding wall 52g2, a light-absorbing resin is more preferably used for the upper part. Furthermore, the material is not limited to two types. Three or more types of materials may be separately used in a height direction to form the light-shielding wall 52.

### 13. Second Variation of Third Configuration Example

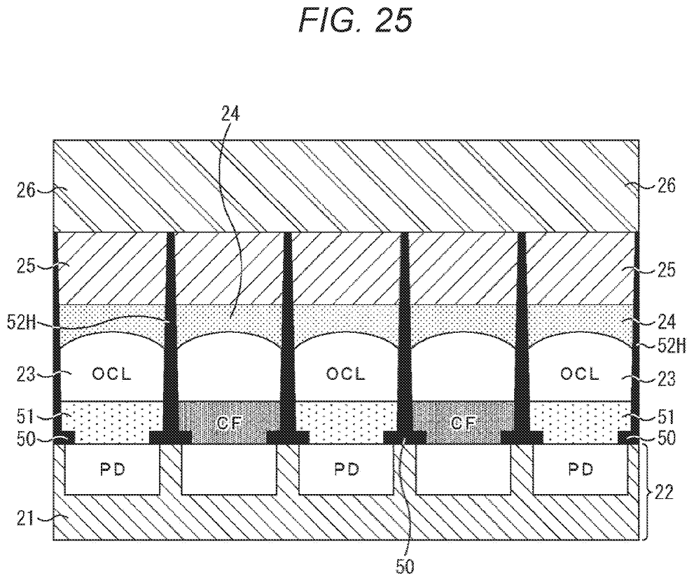

FIG. 25 illustrates a second variation of the third configuration example illustrated in FIG. 21.

In FIG. 25, the same signs are attached to the parts corresponding to those in FIG. 21, and the description of the parts will be appropriately omitted.

In FIG. 25, the light-shielding wall 52G in the third configuration example illustrated in FIG. 21 is replaced with a light-shielding wall 52H. Other configurations in FIG. 25 are similar to those in the third configuration example illustrated in FIG. 21.

The light-shielding wall 52G in the third configuration example illustrated in FIG. 21 has the same thickness (thickness in a plane direction) from the bottom surface on which the light-shielding wall 52G is in contact with the inter-pixel light-shielding film 50 to the upper surface on which the light-shielding wall 52G is in contact with the cover glass 26.

In contrast, in the second variation in FIG. 25, the light-shielding wall 52H has a tapered shape in which the side surface is inclined. The light-shielding wall 52H is thickest at the bottom surface on which the light-shielding wall 52H is in contact with the inter-pixel light-shielding film 50, and thinnest at the upper surface on which the light-shielding wall 52H is in contact with the cover glass 26. The light-shielding wall 52H in plan view has a rectangular shape. The opening area inside the light-shielding wall 52H is minimum at the bottom surface on the side of the CF layer 51, and maximum at the upper surface on the side of the cover glass 26.

In this way, the light-shielding wall 52H having a tapered side surface enables the photodiode PD to capture much incident light, and can improve sensitivity.

Note that the light-shielding wall 52H may include one type of material including metal material such as tungsten (W) and a carbon black resin, or as in the first variation, two or more types of materials may be separately used in the height direction.

### 14. Fourth Configuration Example of Imaging Element

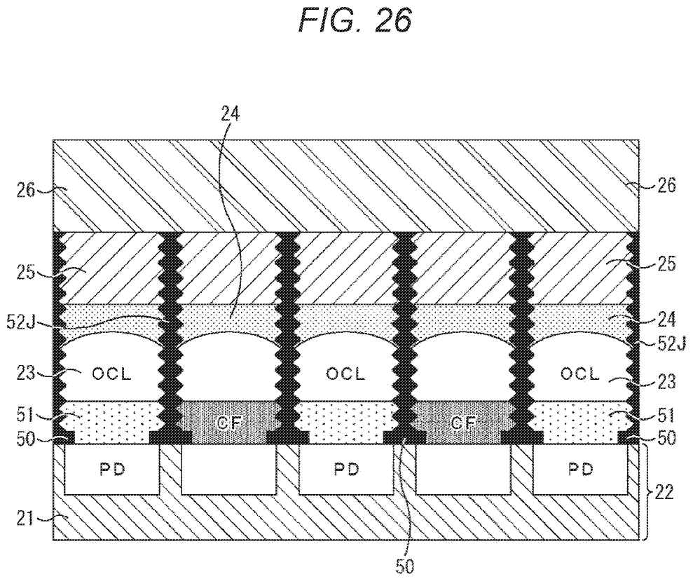

FIG. 26 is a cross-sectional view illustrating a detailed fourth configuration example of the imaging element 1 in FIG. 1.

In FIG. 26, the same signs are attached to the parts corresponding to the above-described other configuration examples, and the description of the parts will be appropriately omitted.

In FIG. 26, the light-shielding wall 52G in the third configuration example illustrated in FIG. 21 is replaced with a light-shielding wall 52J. Other configurations in FIG. 26 are similar to those in the third configuration example illustrated in FIG. 21.

While the light-shielding wall 52G in the third configuration example illustrated in FIG. 21 has a flat side surface without unevenness in cross-sectional view, the light-shielding wall 52J in FIG. 26 has a side surface that is wavy (uneven) in cross-sectional view.

The fourth configuration example and the second configuration example have a commonality in that the light-shielding wall 52J in FIG. 26 has a wavy side surface as compared to the second configuration example illustrated in FIG. 9. The fourth configuration example and the second configuration example are different in that, while the light-shielding wall 52J in the fourth configuration example is formed from the CF layer 51 to the lower surface of the cover glass 26 (upper surface of the glass seal resin 25), the light-shielding wall 52D in the second configuration example is formed from the CF layer 51 to a position of the upper surface of the flattening film 24 (lower surface of the glass seal resin 25).

Consequently, the fourth configuration example has the features of both the above-described second and third configuration examples, and exhibits the functions and effects of both thereof. That is, the light-shielding wall 52J formed higher can further inhibit re-reflected light from being incident to the imaging element 1. The light-shielding wall 52J having a wavy side surface in cross-sectional view can further lower the light intensity of reflected light.

### 15. Manufacturing Method in Fourth Configuration Example

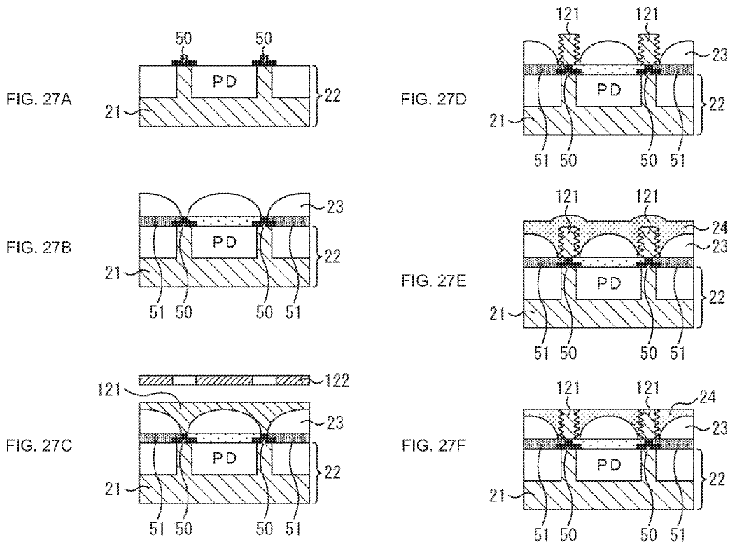

A method of manufacturing the imaging element 1 illustrated in FIG. 26 in the fourth configuration example will be described with reference to FIGS. 27 to 29.

In A of FIG. 27, in a manner similar to that in A of FIG. 4 in the first configuration example, the inter-pixel light-shielding film 50 is formed at a pixel boundary part of the upper surface on the back-surface side of the semiconductor substrate 21 in which, for example, the photodiode PD and the multilayer wiring layer are formed.

Next, as illustrated in B of FIG. 27, the CF layer 51 and the OCL 23 are formed on the upper surface of the photodiode PD. As illustrated in C of FIG. 27, the upper surface of the OCL 23 is coated with the resist 121, and the resist 121 is exposed and developed with the mask 122 having a pattern corresponding to the position where the light-shielding wall 52J is formed. As illustrated in D of FIG. 27, this operation removes the resist 121 at a position other than the position where the light-shielding wall 52J is formed, and the resist 121 has the same wavy structure as the light-shielding wall 52J.

Next, as illustrated in E of FIG. 27, the flattening film 24 is formed with a thickness equal to or greater than the height of the resist 121. The resist 121 is formed in a shape of a light-shielding wall. As illustrated in F of FIG. 27, the flattening film 24 is removed by CMP to the same height as that of the resist 121.

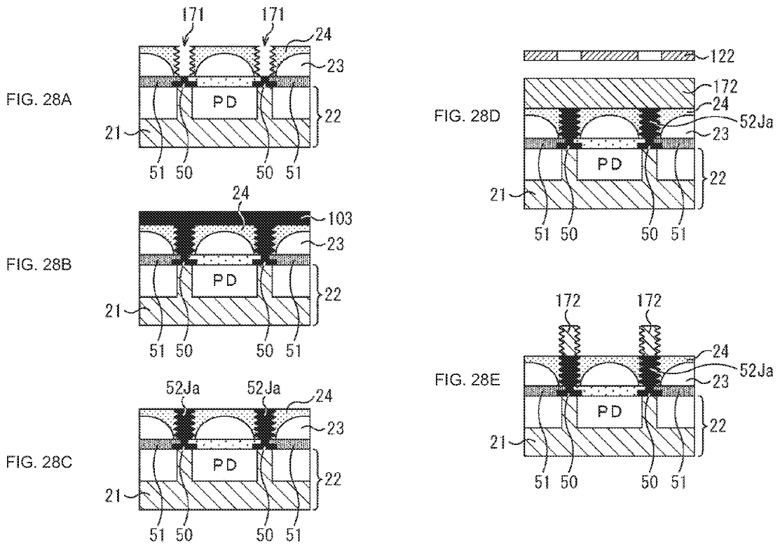

Next, as illustrated in A of FIG. 28, the resist 121 formed in the shape of a light-shielding wall is peeled off to form an opening 171 in the flattening film 24.

Next, as illustrated in B of FIG. 28, the filling material 103 such as tungsten and a carbon black resin fills the interior of the opening 171, and serves as a film on the upper surface of the flattening film 24.

Then, as illustrated in C of FIG. 28, the filling material 103 formed on the upper surface of the flattening film 24 is removed by CMP to form a light-shielding wall 52Ja, which is a part (lower part) of the light-shielding wall 52J.

Subsequently, as illustrated in D of FIG. 28, the upper surfaces of the light-shielding wall 52Ja and the insulating film 123 are coated with a resist 172, and is exposed and developed with the mask 122 having a pattern corresponding to a position where the light-shielding wall 52J is formed. As illustrated in E of FIG. 28, the resist 172 at a position other than the position where the light-shielding wall 52J is formed is removed, and the resist 172 has a wavy structure as the light-shielding wall 52J. For example, an organic material capable of withstanding a high temperature, such as “IX370G” manufactured by JSR Corporation can be used for the resist 172.

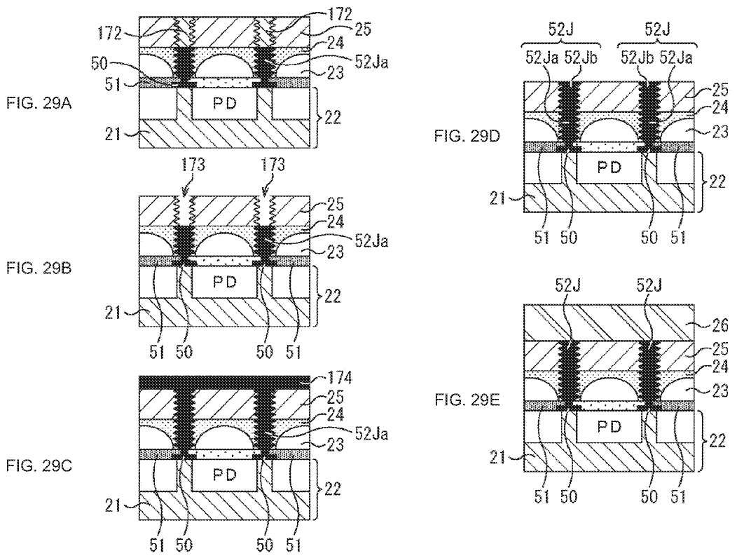

Next, as illustrated in A of FIG. 29, the glass seal resin 25 is formed with a thickness equal to or greater than the height of the resist 172 formed in a shape of a light-shielding wall. As illustrated in B of FIG. 29, the resist 172 formed in the shape of a light-shielding wall is peeled off. An opening 173 is formed in the glass seal resin 25.

Next, as illustrated in C of FIG. 29, filling material 174 such as tungsten and a carbon black resin fills the interior of the opening 173, and serves as a film on the upper surface of the glass seal resin 25.

Then, as illustrated in D of FIG. 29, the filling material 174 formed on the upper surface of the glass seal resin 25 is removed by CMP to form a light-shielding wall 52Jb, which is the upper rest part of the light-shielding wall 52J. The light-shielding wall 52Ja and the light-shielding wall 52Jb constitute the light-shielding wall 52J. The light-shielding wall 52Ja is formed in the same layer as that of the flattening film 24. The light-shielding wall 52Jb is formed in the same layer as that of the glass seal resin 25.

Finally, as illustrated in E of FIG. 29, the cover glass 26 is bonded to the upper surfaces of the glass seal resin 25 and the light-shielding wall 52J to complete the imaging element 1 according to the fourth configuration example.

### 16. Fifth Configuration Example of Imaging Element

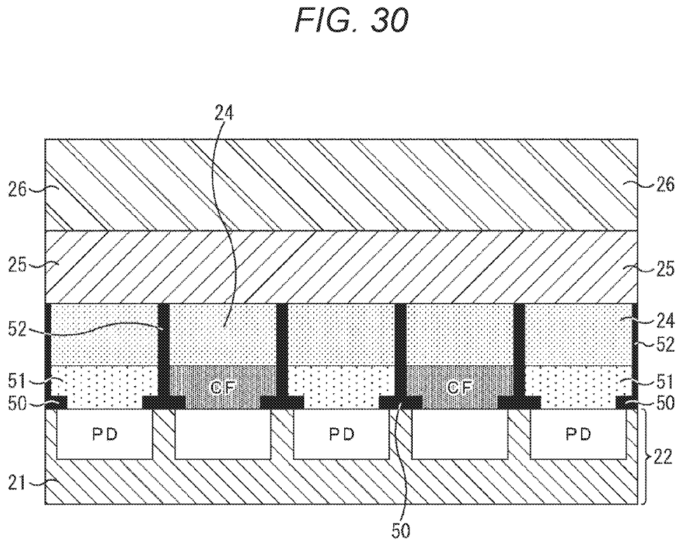

FIG. 30 is a cross-sectional view illustrating a detailed fifth configuration example of the imaging element 1 in FIG. 1.

In FIG. 30, the same signs are attached to the parts corresponding to the first configuration example illustrated in FIG. 2, and the description of the parts will be appropriately omitted.

In FIG. 30, the OCL 23 formed between the CF layer 51 and the flattening film 24 in FIG. 2 is omitted, and only the flattening film 24 is formed between the CF layer 51 and the glass seal resin 25. Other configurations in FIG. 30 are similar to those in the first configuration example illustrated in FIG. 2. In this way, the OCL 23 can be omitted since the light-shielding wall 52 has a role of an optical waveguide.

Note that not a material of the flattening film 24 but that of the OCL 23 may fill the space between the CF layer 51 and the glass seal resin 25. Furthermore, the glass seal resin 25 may fill the space. That is, a light-transmitting layer is required to be made by one of materials of the OCL 23, the flattening film 24, and the glass seal resin 25 without forming a lens shape between the CF layer 51 and the glass seal resin 25. The refractive index of the light-transmitting layer between the CF layer 51 and the glass seal resin 25 may be set between the refractive index of the cover glass 26 and that of the CF layer 51.

The light-shielding wall 52 can include one type of material including, for example, metal material such as tungsten (W) and a carbon black resin. In addition, in a similar manner to that of the first variation of the first configuration example illustrated in FIG. 7, the light-shielding wall 52 may be formed by separately using materials different between the upper part and the lower part.

In the fifth configuration example as well, the light-shielding wall 52 formed higher than the CF layer 51 to the position of the upper surface of the flattening film 24 can reduce false signal output called a flare and ghost.

The configuration in which the OCL 23 is omitted can be applied to the above-described other configuration examples and variations.

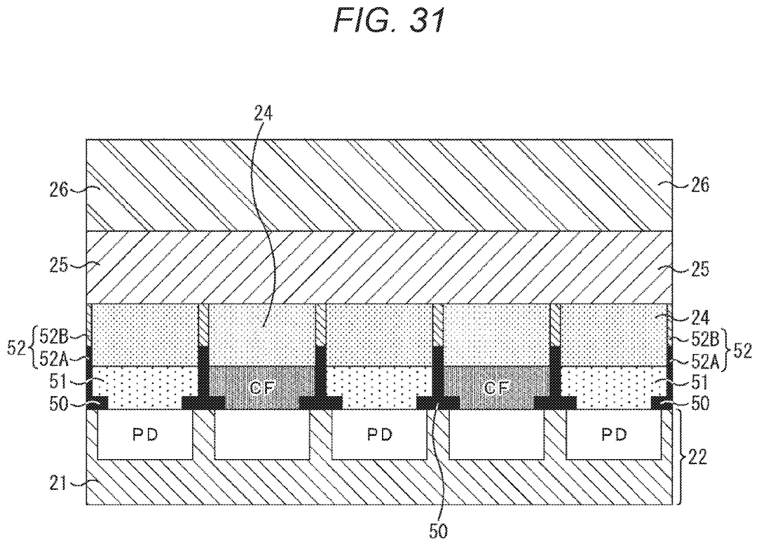

FIG. 31 is a cross-sectional view illustrating a configuration in which the OCL 23 is omitted, the configuration being applied to the first variation of the first configuration example illustrated in FIG. 7.

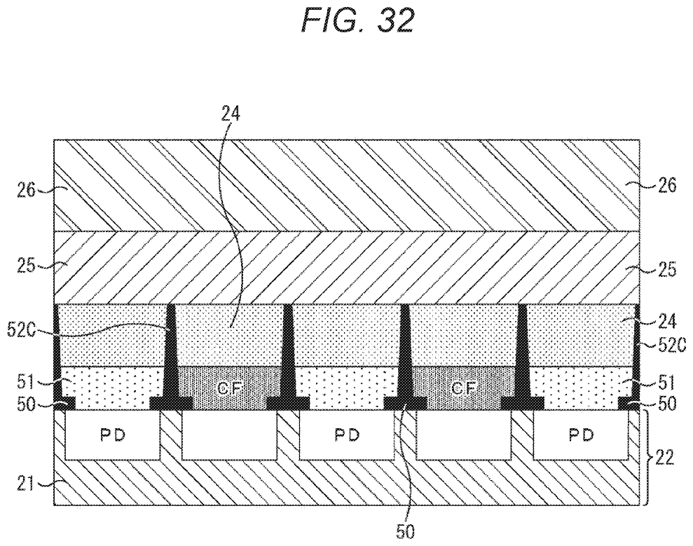

FIG. 32 is a cross-sectional view illustrating the configuration in which the OCL 23 is omitted, the configuration being applied to the second variation of the first configuration example illustrated in FIG. 8.

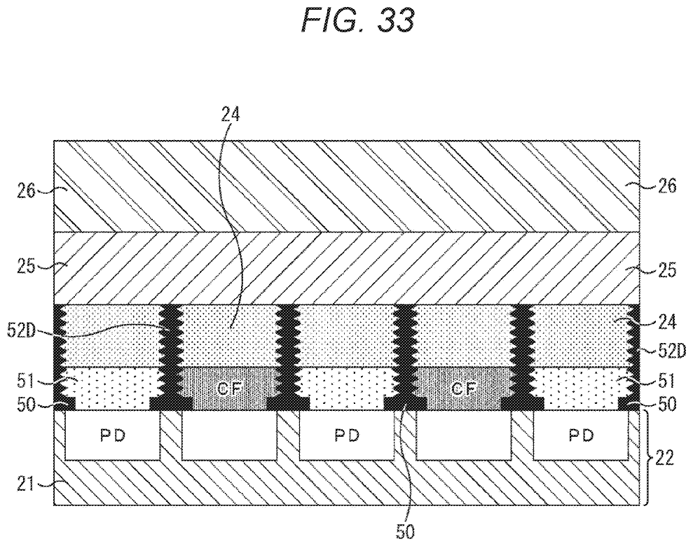

FIG. 33 is a cross-sectional view illustrating the configuration in which the OCL 23 is omitted, the configuration being applied to the second configuration example illustrated in FIG. 9.

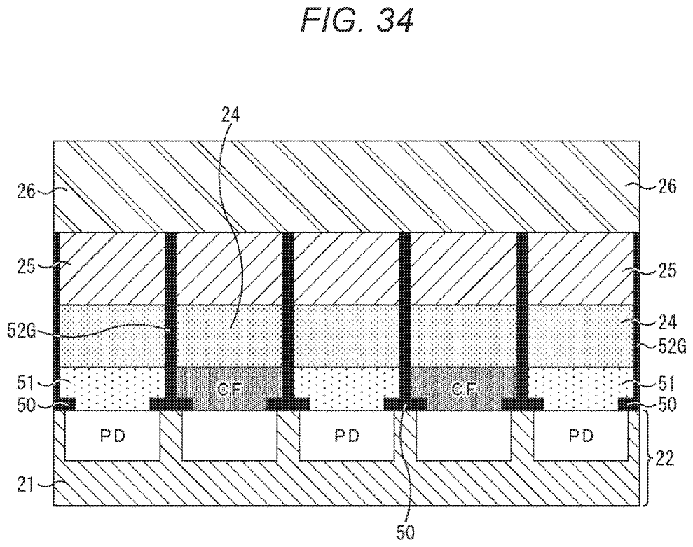

FIG. 34 is a cross-sectional view illustrating the configuration in which the OCL 23 is omitted, the configuration being applied to the third configuration example illustrated in FIG. 21.

Although illustration is omitted, the configuration in which the OCL 23 is omitted can be similarly applied to the first variation of the third configuration example illustrated in FIG. 24, the second variation of the third configuration example illustrated in FIG. 25, the fourth configuration example illustrated in FIG. 26, and variations thereof.

### 17. Height of Light-Shielding Wall

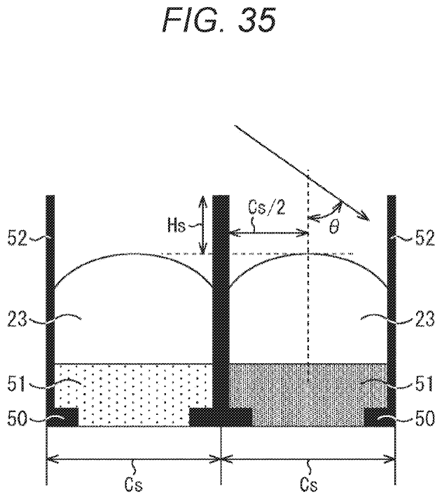

Next, a set value of the height of the light-shielding wall 52 will be described with reference to FIG. 35.

The light-shielding wall 52 formed higher than at least the CF layer 51 can reduce false signal output called as a flare and ghost. The light-shielding wall 52 formed at the same height as that of the OCL 23 or higher than the OCL 23 can further reduce the false signal output.

The height of the light-shielding wall 52 in a case of forming the light-shielding wall 52 higher than the OCL 23 can be determined in accordance with an incidence angle of incident light to be cut. Specifically, a protrusion amount Hs of the light-shielding wall 52 is calculated by Expression (1) below using an incidence angle θ and a pixel size Cs. As illustrated in FIG. 35, a protrusion amount of a part that protrudes to the upper side of the OCL 23 of the light-shielding wall 52 is defined as Hs, a pixel size is defined as Cs, and an incidence angle of incident light is defined as θ1.

Hs=(Cs/2)×tan(90−θ) (1)

An incidence angle to be cut is substituted into the incidence angle θ in Expression (1) above. For example, in a case of cutting incident light having an incidence angle of 60° or more, 60 is substituted into θ.

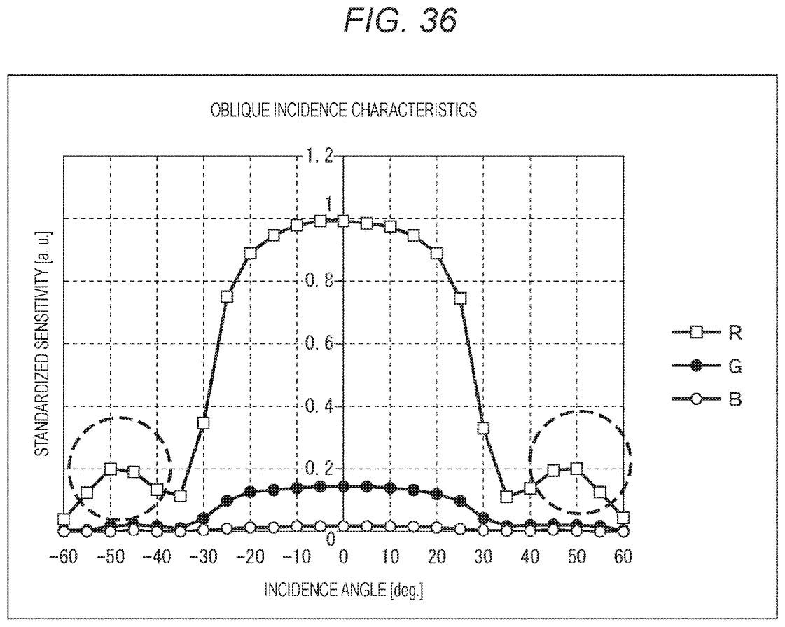

FIG. 36 illustrates oblique incidence characteristics indicating the relation between the incidence angle θ of incident light and output sensitivity for each color of R, G, and B. In FIG. 36, the light-shielding wall 52 is similar in height to the OCL 23.

According to the oblique incidence characteristics in FIG. 36, output sensitivity is increased by a ghost component at incidence angles of 40 degrees or more. The incidence angles correspond to a part surrounded by a dashed line of R pixel. It can be seen that the light-shielding wall 52 needs to be made higher.

Furthermore, according to the oblique incidence characteristics in FIG. 36, it can be seen that the ghost component has a large influence on the R pixel among the R pixel, the G pixel, and the B pixel. Therefore, as illustrated in FIG. 20, a sufficient effect is exerted even in a case where only the R pixel has a structure of the light-shielding wall 52 having an uneven shape in plan view.

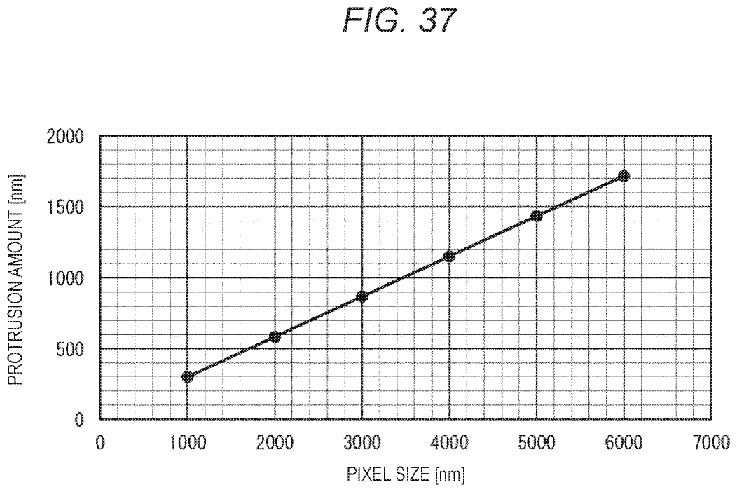

FIG. 37 illustrates the relation between the pixel size Cs and the protrusion amount Hs in a case where the incidence angle θ is set at 60 in Expression (1). As the pixel size Cs is increased, the protrusion amount Hs also needs to be increased.

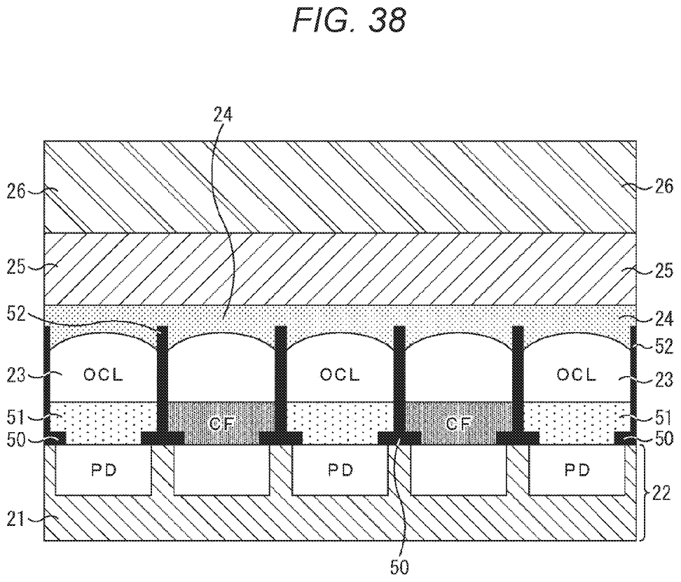

Note that, as described above, the protrusion amount Hs of the light-shielding wall 52 is only required to secure at least an amount calculated in Expression (1) in accordance with the pixel size Cs and the incidence angle θ to be cut. Thus, a structure in which the uppermost surface of the light-shielding wall 52 is not in contact with the glass seal resin 25 as illustrated in FIG. 38 is possible, for example. The structure as illustrated in FIG. 38 is obtained in a case of forming the thick flattening film 24 and not aligning the height of the flattening film 24 with that of the light-shielding wall 52.

### 18. Conclusion

As described above, the imaging element 1 in FIG. 1 includes: a semiconductor substrate 21 including a photodiode PD for each pixel, the photodiode PD photoelectrically converting incident light; a CF layer 51 that is formed on the semiconductor substrate 21 and that passes the incident light of a predetermined wavelength; a light-shielding wall 52 that is formed at a pixel boundary on the semiconductor substrate 21 so as to have a height greater than that of the CF layer 51; and a cover glass 26 that is disposed via the glass seal resin 25 and that protects an upper-surface side of the CF layer 51.

The light-shielding wall 52 formed higher than the CF layer 51 can reflect or absorb light that is re-reflected at the cover glass 26 or the IR cut filter 72 and is again incident to the imaging element 1, and thus can reduce false signal output called a flare and ghost.

### 19. Configuration Example of Solid-State Imaging Apparatus Applicable as Imaging Substrate

A non-laminated solid-state imaging apparatus as described below and a laminated solid-state imaging apparatus including a plurality of laminated substrates can be applied as the above-described imaging substrate 11.

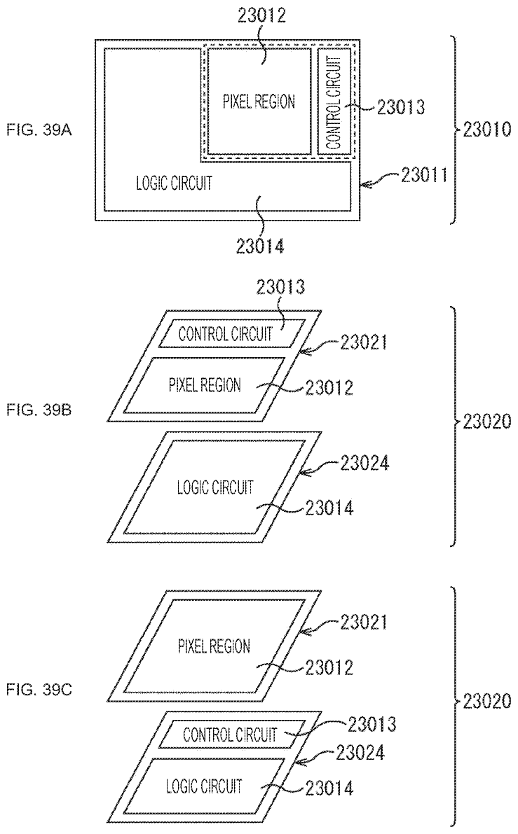

FIG. 39 outlines a configuration example of a solid-state imaging apparatus applicable as the imaging substrate 11.

A of FIG. 39 illustrates a schematic configuration example of a non-laminated solid-state imaging apparatus. As illustrated in A of FIG. 39, a solid-state imaging apparatus 23010 has one die (semiconductor substrate) 23011. A pixel region 23012, a control circuit 23013, and a logic circuit 23014 are mounted on the die 23011. In the pixel region 23012, pixels are disposed in an array. The control circuit 23013 drives the pixels, and performs various controls. The logic circuit 23014 processes a signal.

B and C of FIG. 39 illustrate schematic configuration examples of a laminated solid-state imaging apparatus. As illustrated in B and C of FIG. 14, a solid-state imaging apparatus 23020 includes a sensor die 23021 and a logic die 23024. The two dies are laminated and electrically connected to be one semiconductor chip.

In B of FIG. 39, the pixel region 23012 and the control circuit 23013 are mounted on the sensor die 23021. The logic circuit 23014 is mounted on the logic die 23024. The logic circuit 23014 includes a signal processing circuit that processes a signal.

In C of FIG. 39, the pixel region 23012 is mounted on the sensor die 23021. The control circuit 23013 and the logic circuit 23014 are mounted on the logic die 23024.

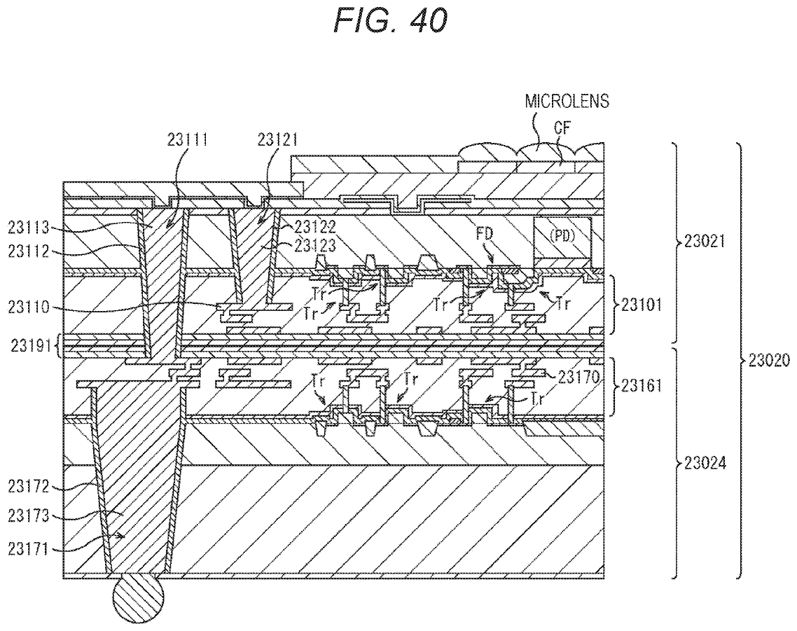

FIG. 40 is a cross-sectional view illustrating a first configuration example of the laminated solid-state imaging apparatus 23020.

For example, a photodiode (PD) constituting a pixel that forms the pixel region 23012, a floating diffusion (FD), a Tr (MOS FET), and a Tr that forms the control circuit 23013 are formed on the sensor die 23021. Furthermore, a wiring layer 23101 is formed on the sensor die 23021. The wiring layer 23101 includes wiring 23110 of a plurality of, three in the example, layers. Note that (Tr that forms) the control circuit 23013 can be configured not at the sensor die 23021 but at the logic die 23024.

A Tr constituting the logic circuit 23014 is formed on the logic die 23024. Furthermore, a wiring layer 23161 is formed on the logic die 23024. The wiring layer 23161 includes wiring 23170 of a plurality of, three in the example, layers. Furthermore, a connection hole 23171 is formed in the logic die 23024. An insulating film 23172 is formed on the inner wall surface of the connection hole 23171. A connection conductor 23173 fills the connection hole 23171. The connection conductor 23173 is connected to, for example, the wiring 23170.

The sensor die 23021 and the logic die 23024 are stuck together such that the wiring layers 23101 and 23161 thereof face each other, and thereby the laminated solid-state imaging apparatus 23020 in which the sensor die 23021 and the logic die 23024 are laminated is configured. A film 23191 such as a protective film is formed on a surface where the sensor die 23021 and the logic die 23024 are stuck together.

A connection hole 23111 is formed in the sensor die 23021. The connection hole 23111 penetrates the sensor die 23021 from the back-surface side (side where light is incident to a PD) (upper side) of the sensor die 23021 to reach the wiring 23170 of the uppermost layer of the logic die 23024. Furthermore, a connection hole 23121 is formed in the sensor die 23021. The connection hole 23121 comes close to the connection hole 23111, and reaches the wiring 23110 of the first layer from the back-surface side of the sensor die 23021. An insulating film 23112 is formed on the inner wall surface of the connection hole 23111, and an insulating film 23122 is formed on the inner wall surface of the connection hole 23121. Then, connection conductors 23113 and 23123 fill the connection holes 23111 and 23121, respectively. The connection conductors 23113 and 23123 are electrically connected on the back-surface side of the sensor die 23021, whereby the sensor die 23021 and the logic die 23024 are electrically connected via the wiring layer 23101, the connection hole 23121, the connection hole 23111, and the wiring layer 23161.

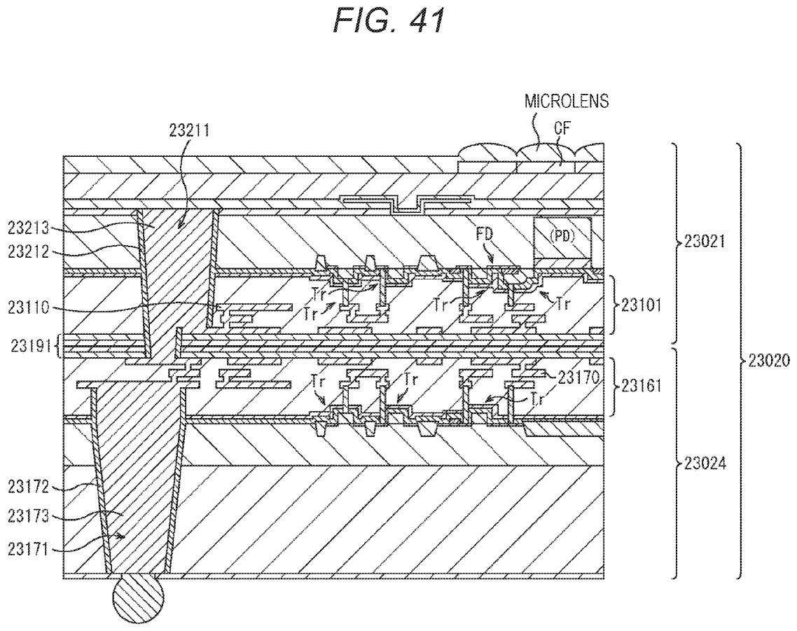

FIG. 41 is a cross-sectional view illustrating a second configuration example of the laminated solid-state imaging apparatus 23020.

In the second configuration example of the solid-state imaging apparatus 23020, one connection hole 23211 formed on the sensor die 23021 electrically connects the ((wiring 23110) of the wiring layer 23101 of) the sensor die 23021 and the ((wiring 23170) of the wiring layer 23161 of) the logic die 23024.

That is, in FIG. 41, the connection hole 23211 is formed so as to penetrate the sensor die 23021 from the back-surface side of the sensor die 23021 to reach the wiring 23170 of the uppermost layer of the logic die 23024, and to reach the wiring 23110 of the uppermost layer of the sensor die 23021. An insulating film 23212 is formed on the inner wall surface of the connection hole 23211, and a connection conductor 23213 fill the connection hole 23211. In FIG. 40 above, two connection holes 23111 and 23121 electrically connect the sensor die 23021 and the logic die 23024, whereas, in FIG. 41, one connection hole 23211 electrically connects the sensor die 23021 and the logic die 23024.

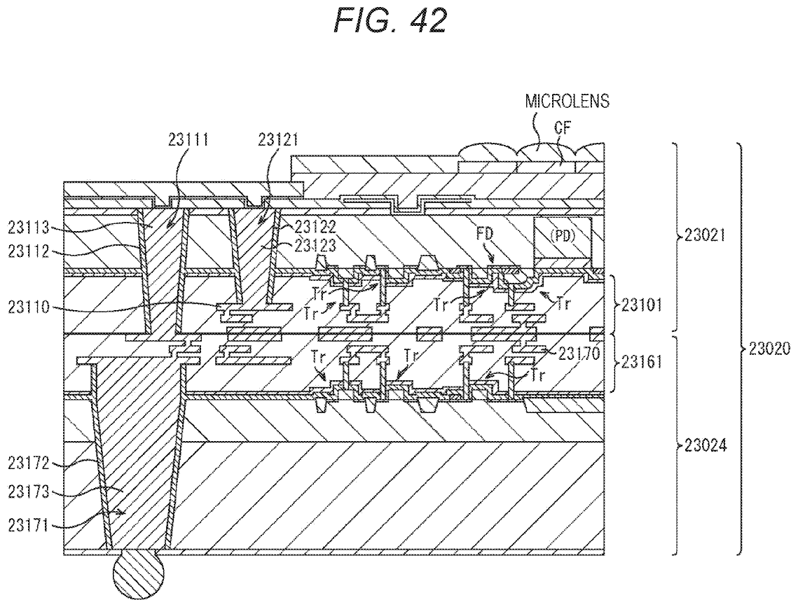

FIG. 42 is a cross-sectional view illustrating a third configuration example of the laminated solid-state imaging apparatus 23020.

The solid-state imaging apparatus 23020 in FIG. 42 is different from that in FIG. 17 in that the film 23191 such as a protective film is not formed on a surface where the sensor die 23021 and the logic die 23024 are stuck together. In FIG. 17, the film 23191 such as a protective film is formed on a surface where the sensor die 23021 and the logic die 23024 are stuck together.

The solid-state imaging apparatus 23020 in FIG. 42 is configured by overlapping the sensor die 23021 and the logic die 23024 such that the wiring 23110 and the wiring 23170 are brought into direct contact, heating the wiring 23110 and the wiring 23170 while applying predetermined weight, and directly joining the wiring 23110 and the wiring 23170.

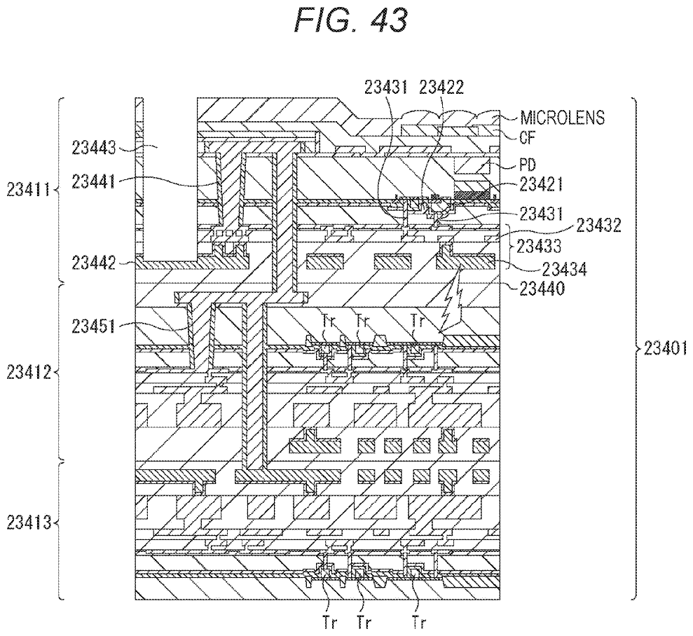

FIG. 43 is a cross-sectional view illustrating another configuration example of the laminated solid-state imaging apparatus to which the technology according to the disclosure can be applied.

In FIG. 43, a solid-state imaging apparatus 23401 has a three-layer laminated structure in which three dies of a sensor die 23411, a logic die 23412, and a memory die 23413 are laminated.

The memory die 23413 includes, for example, a memory circuit that stores data temporarily required in signal processing performed at the logic die 23412.

Although, in FIG. 43, the logic die 23412 and the memory die 23413 are laminated under the sensor die 23411 in the order, the logic die 23412 and the memory die 23413 can be laminated under the sensor die 23411 in the opposite order, that is, the order of the memory die 23413 and the logic die 23412.

Note that, in FIG. 43, a PD serving as a photoelectric conversion unit for a pixel and a source/drain region of a pixel Tr are formed in the sensor die 23411.

A gate electrode is formed around the PD via a gate insulating film. Pixels Tr23421 and Tr23422 are formed by the gate electrode and a pair of source/drain regions.

The pixel Tr23421 adjacent to the PD corresponds to a transfer Tr, and one of the pair of source/drain regions constituting the pixel Tr23421 corresponds to the FD.

Furthermore, an interlayer insulating film is formed in the sensor die 23411, and a connection hole is formed in the interlayer insulating film. A connection conductor 23431 connected to the pixel Tr23421 and the pixel Tr23422 is formed in the connection hole.

Moreover, a wiring layer 23433 is formed on the sensor die 23411. The wiring layer 23433 includes wiring 23432 of a plurality of layers connected to each connection conductor 23431.

Furthermore, an aluminum pad 23434 serving as an electrode for external connection is formed on the lowermost layer of the wiring layer 23433 of the sensor die 23411. That is, in the sensor die 23411, the aluminum pad 23434 is formed at a position closer to a bonding surface 23440 with the logic die 23412 than the wiring 23432. The aluminum pad 23434 is used as one end of wiring related to input/output of a signal from/to the outside.

Furthermore, a contact 23441 used for electrical connection with the logic die 23412 is formed on the sensor die 23411. The contact 23441 is connected to a contact 23451 of the logic die 23412 and also to an aluminum pad 23442 of the sensor die 23411.

Then, a pad hole 23443 is formed in the sensor die 23411 so as to reach the aluminum pad 23442 from the back-surface side (upper side) of the sensor die 23411.

The structure of a solid-state imaging apparatus as described above can be applied to the imaging substrate 11.

### 20. Example of Application to Electronic Appliance

The technology according to the disclosure is not limited to application to a solid-state imaging apparatus. That is, the technology according to the disclosure can be applied to overall electronic appliances using a solid-state imaging apparatus in an image capturing unit (photoelectric conversion unit). The overall electronic appliances include, for example, imaging apparatuses such as digital still cameras and video cameras, mobile terminal apparatuses having an imaging function, and copying machines using a solid-state imaging apparatus in an image reading unit. The solid-state imaging apparatus may be formed in one chip or in a module having an imaging function. In the module, an imaging unit and a signal processing unit or an optical system are packaged together.

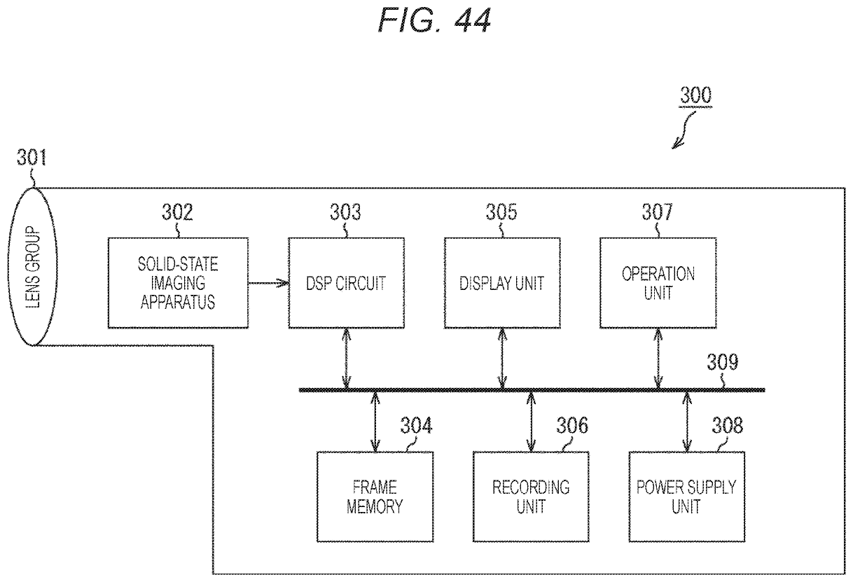

FIG. 44 is a block diagram illustrating a configuration example of an imaging apparatus as an electronic appliance to which the technology according to the disclosure is applied.

An imaging apparatus 300 in FIG. 44 includes an optical unit 301, a solid-state imaging apparatus (imaging device) 302, and a digital signal processor (DSP) circuit 303. The optical unit 301 includes, for example, a lens group. The solid-state imaging apparatus 302 adopts the configuration of the imaging element 1 in FIG. 1. The DSP circuit 303 is a camera signal processing circuit. Furthermore, the imaging apparatus 300 also includes a frame memory 304, a display unit 305, a recording unit 306, an operation unit 307, and a power supply unit 308. The DSP circuit 303, the frame memory 304, the display unit 305, the recording unit 306, the operation unit 307, and the power supply unit 308 are mutually connected via a bus line 309.

The optical unit 301 captures incident light (image light) from a subject, and forms an image on an imaging surface of a solid-state imaging apparatus 302. The solid-state imaging apparatus 302 converts an amount of incident light which forms an image on the imaging surface with the optical unit 301 into an electrical signal on a pixel basis, and outputs the electrical signal as a pixel signal. The imaging element 1 in FIG. 1, that is, an image sensor package that reduces false signal output due to reflected light of incident light can be used as the solid-state imaging apparatus 302.

The display unit 305 includes, for example, a thin display such as a liquid crystal display (LCD) or an organic electro luminescence (EL) display, and displays a moving image or a still image captured by the solid-state imaging apparatus 302. The recording unit 306 records a moving image or a still image captured by the solid-state imaging apparatus 302 in a recording medium such as a hard disk and a semiconductor memory.

The operation unit 307 issues an operation command for various functions of the imaging apparatus 300 under the operation of a user. The power supply unit 308 appropriately supplies various power supplies serving as operation power supplies for the DSP circuit 303, the frame memory 304, the display unit 305, the recording unit 306, and the operation unit 307 to these supply targets.

As described above, the CSP structure of the above-described imaging element 1 adopted as the solid-state imaging apparatus 302 can reduce false signal output due to reflected light of incident light. Consequently, the imaging apparatus 300 such as a video camera, a digital still camera, and a camera module for a mobile device such as a mobile phone can generate and output a high-quality image.

### 21. Usage Example of Image Sensor

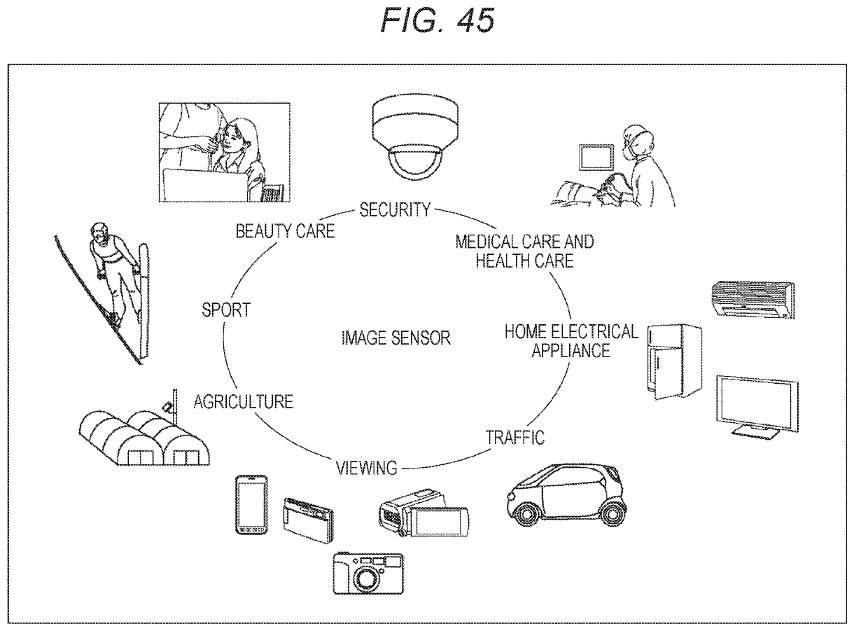

FIG. 45 illustrates a usage example of an image sensor using the above-described imaging element 1.

An image sensor using the above-described image sensor PKG1 can be used in various cases of sensing light such as visible light, infrared light, ultraviolet light, and X-ray, for example, as described below.
An apparatus that captures an image provided for viewing, such as a digital camera and a portable instrument with a camera function
An apparatus provided for traffic, such as an in-vehicle sensor, a monitoring camera, and a distance measurement sensor, the in-vehicle sensor capturing an image of, for example, the front, back, surroundings, and inside of an automobile for safe driving such as automatic stop, recognition of the state of a driver, and the like, the monitoring camera monitoring a running vehicle and a road, the distance measurement sensor measuring, for example, a distance between vehicles
An apparatus provided for a home electrical appliance such as a TV, a refrigerator, and an air conditioner for capturing an image of a gesture of a user and operating an instrument in accordance with the gesture
An apparatus provided for medical care and health care, such as an endoscope and an apparatus for capturing an image of a blood vessel by receiving infrared light
An apparatus provided for security, such as a monitoring camera for security and a camera for person authentication
An apparatus provided for beauty care, such as a skin measuring instrument for capturing an image of skin and a microscope for capturing an image of a scalp
An apparatus provided for sports, such as an action camera and a wearable camera for sports
An apparatus provided for agriculture, such as a camera for monitoring the states of a field and crops

### 22. Example of Application to In-Vivo Information Acquisition System

The technology (the present technology) according to the disclosure can be applied to various products as described above. For example, the technology according to the disclosure may be applied to a system for acquiring in-vivo information of a patient using a capsule endoscope.

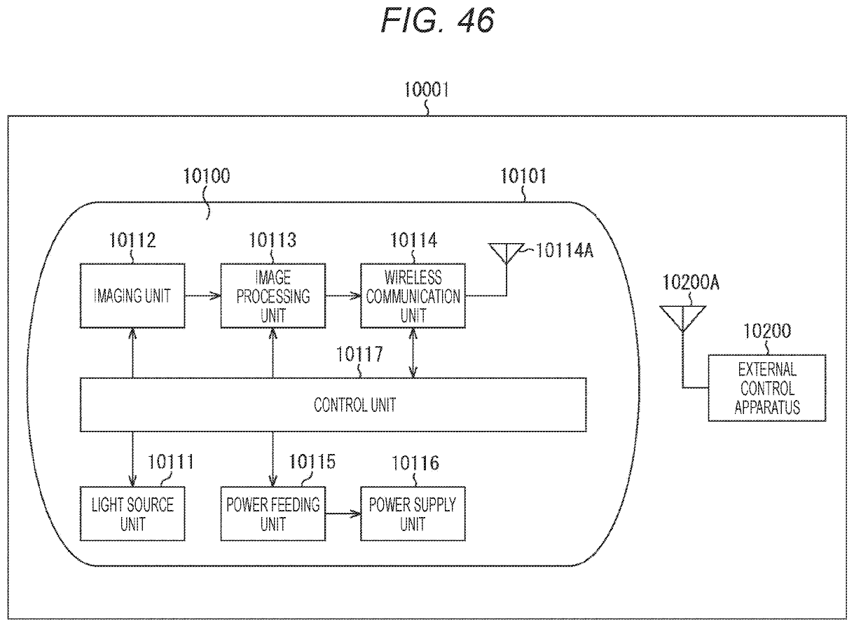

FIG. 46 is a block diagram illustrating one example of the schematic configuration of a system for acquiring in-vivo information of a patient using a capsule endoscope, to which the technology according to the disclosure can be applied.

An in-vivo information acquisition system 10001 includes a capsule endoscope 10100 and an external control apparatus 10200.

The capsule endoscope 10100 is swallowed by a patient at the time of examination. The capsule endoscope 10100 has an imaging function and a wireless communication function. The capsule endoscope 10100 sequentially captures an image (hereinafter also referred to an in-vivo image) of the interior of an organ, such as a stomach and intestines, at a predetermined interval while moving inside the organ by peristalsis until being naturally discharged from a patient. The capsule endoscope 10100 sequentially and wirelessly transmits information regarding the in-vivo image to the external control apparatus 10200 outside the body.

The external control apparatus 10200 comprehensively controls operations of the in-vivo information acquisition system 10001. Furthermore, the external control apparatus 10200 receives information regarding an in-vivo image transmitted from the capsule endoscope 10100, and generates image data for displaying the in-vivo image on a display (not illustrated) on the basis of the received information regarding the in-vivo image.

In this way, the in-vivo information acquisition system 10001 can acquire an in-vivo image obtained by imaging the interior of a patient from swallow to discharge of the capsule endoscope 10100 as needed.

The configurations and functions of the capsule endoscope 10100 and the external control apparatus 10200 will be described in more detail.

The capsule endoscope 10100 includes a capsule housing 10101. In the housing 10101, a light source unit 10111, an imaging unit 10112, an image processing unit 10113, a wireless communication unit 10114, a power feeding unit 10115, a power supply unit 10116, and a control unit 10117 are housed.

The light source unit 10111 includes a light source such as, for example, a light emitting diode (LED), and applies light to an imaging field of view of the imaging unit 10112.

The imaging unit 10112 includes an imaging element and an optical system. The optical system includes a plurality of lenses provided in the front stage of the imaging element. Reflected light (hereinafter referred to as observation light) of light applied to a body tissue to be observed is received by the optical system, and is incident to the imaging element. In the imaging unit 10112, observation light incident to an imaging element is photoelectrically converted, and an image signal corresponding to the observation light is generated. An image signal generated by the imaging unit 10112 is provided to the image processing unit 10113.

The image processing unit 10113 includes a processor such as a central processing unit (CPU) or a graphics processing unit (GPU), and performs various types of signal processing on an image signal generated by the imaging unit 10112. The image processing unit 10113 provides the image signal on which the signal processing is performed to the wireless communication unit 10114 as RAW data.

The wireless communication unit 10114 performs predetermined processing such as modulation processing on the image signal on which the signal processing is performed by the image processing unit 10113, and transmits the image signal to the external control apparatus 10200 via an antenna 10114A. Furthermore, the wireless communication unit 10114 receives a control signal related to drive control of the capsule endoscope 10100 from the external control apparatus 10200 via the antenna 10114A. The wireless communication unit 10114 provides the control signal received from the external control apparatus 10200 to the control unit 10117.

The power feeding unit 10115 includes, for example, an antenna coil for receiving power, a power regeneration circuit, and a booster circuit. The power regeneration circuit regenerates power from current generated in the antenna coil. The power feeding unit 10115 generates power by using, a so-called principle of non-contact charging.

The power supply unit 10116 includes a secondary battery, and stores power generated by the power feeding unit 10115. In FIG. 46, for example, an arrow indicating a supply destination of power from the power supply unit 10116 is not illustrated to avoid the figure from being complicated. Power stored in the power supply unit 10116 can be supplied to the light source unit 10111, the imaging unit 10112, the image processing unit 10113, the wireless communication unit 10114, and the control unit 10117 to be used for driving these units.

The control unit 10117 includes a processor such as a CPU, and appropriately controls the drives of the light source unit 10111, the imaging unit 10112, the image processing unit 10113, the wireless communication unit 10114, and the power feeding unit 10115 in accordance with a control signal transmitted from the external control apparatus 10200.

The external control apparatus 10200 includes, for example, a processor such as a CPU and a GPU, or a microcomputer or a control substrate in which a processor and a storage element such as a memory are mixedly mounted. The external control apparatus 10200 controls the operation of the capsule endoscope 10100 by transmitting a control signal to the control unit 10117 of the capsule endoscope 10100 via an antenna 10200A. In the capsule endoscope 10100, for example, a condition of light applied to an observation target in the light source unit 10111 can be changed by a control signal from the external control apparatus 10200. Furthermore, an imaging condition (e.g., a frame rate, an exposure value, and the like in the imaging unit 10112) can be changed by a control signal from the external control apparatus 10200. Furthermore, the content of processing in the image processing unit 10113 and a condition (e.g., transmission interval, the number of transmitted images, and the like) of the wireless communication unit 10114 transmitting an image signal may be changed by a control signal from the external control apparatus 10200.

Furthermore, the external control apparatus 10200 performs various types of image processing on an image signal transmitted from the capsule endoscope 10100, and generates image data for displaying a captured in-vivo image on a display. The image processing can include various types of signal processing such as, for example, development processing (demosaic processing), image quality improving processing (e.g., band emphasizing processing, super-resolution processing, noise reduction (NR) processing, and/or camera-shake correction processing), and/or enlargement processing (electronic zoom processing). The external control apparatus 10200 controls the drive of the display, and displays an in-vivo image captured on the basis of generated image data. Alternatively, the external control apparatus 10200 may cause a recording apparatus (not illustrated) to record the generated image data, or cause a printing apparatus (not illustrated) to print and output the generated image data.

One example of the in-vivo information acquisition system to which the technology according to the disclosure can be applied has been described above. The technology according to the disclosure can be applied to the imaging unit 10112 among the above-described configurations. Specifically, the above-described imaging element 1 can be applied as the imaging unit 10112. The imaging unit 10112 to which the technology according to the disclosure is applied can reduce false signal output called a flare and ghost. The imaging unit 10112 can thus generate an in-vivo image with high quality, and contribute to improvement of examination precision.

### 23. Example of Application to Endoscopic Surgical System

The technology according to the disclosure may be applied to, for example, an endoscopic surgical system.

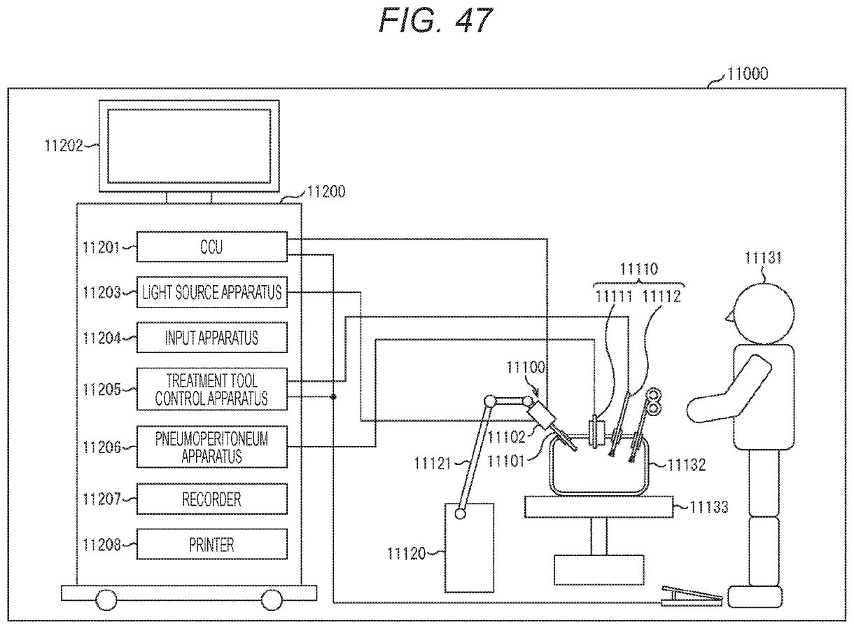

FIG. 47 illustrates one example of the schematic configuration of an endoscopic surgical system to which the technology according to the disclosure can be applied.

In FIG. 47, a surgeon (doctor) 11131 performs surgery on a patient 11132 on a patient bed 11133 by using an endoscopic surgical system 11000. As illustrated in the figure, the endoscopic surgical system 11000 includes an endoscope 11100, other surgical tools 11110 such as a pneumoperitoneum tube 11111 and an energy treatment tool 11112, a support arm apparatus 11120, and a cart 11200. The support arm apparatus 11120 supports the endoscope 11100. Various apparatuses for endoscopic surgery are mounted in the cart 11200.

The endoscope 11100 includes a lens barrel 11101 and a camera head 11102. A region, having a length predetermined from the distal end, of the lens barrel 11101 is inserted into a body cavity of the patient 11132. The camera head 11102 is connected to the proximal end of the lens barrel 11101. Although, in the illustrated example, the endoscope 11100, which is configured as a so-called rigid mirror having the rigid lens barrel 11101, is illustrated, the endoscope 11100 may be configured as a so-called flexible mirror having a flexible lens barrel.

An opening into which an objective lens is fitted is provided at the distal end of the lens barrel 11101. A light source apparatus 11203 is connected to the endoscope 11100. Light generated by the light source apparatus 11203 is guided to the distal end of the lens barrel by a light guide extending inside the lens barrel 11101, and applied to an observation target in the body cavity of the patient 11132 via the objective lens. Note that the endoscope 11100 may be a forward-viewing endoscope, an oblique-viewing endoscope, or a side-viewing endoscope.

An optical system and an imaging element are provided inside the camera head 11102. Reflected light (observation light) from the observation target is collected on the imaging element by the optical system. The observation light is photoelectrically converted by the imaging element, and an electrical signal corresponding to the observation light, that is, an image signal corresponding to the observation image is generated. The image signal is transmitted to a camera control unit (CCU) 11201 as RAW data.

The CCU 11201 includes, for example, a central processing unit (CPU) and a graphics processing unit (GPU), and comprehensively controls the operations of the endoscope 11100 and a display 11202. Furthermore, the CCU 11201 receives an image signal from the camera head 11102. The CCU 11201 performs various pieces of image processing for displaying an image based on the image signal on the image signal. The various pieces of image processing include, for example, development processing (demosaic processing) and the like.

The display 11202 displays an image based on the image signal on which image processing is performed by the CCU 11201 under the control of the CCU 11201.

The light source apparatus 11203 includes a light source such as, for example, a light emitting diode (LED), and supplies irradiation light at the time of capturing an image of, for example, a surgical site to the endoscope 11100.

An input apparatus 11204 is an input interface for the endoscopic surgical system 11000. A user can input various pieces of information and instructions to the endoscopic surgical system 11000 via the input apparatus 11204. For example, the user inputs, for example, an instruction to change an imaging condition (e.g., type of irradiation light, magnification, and focal length) in the endoscope 11100.

A treatment tool control apparatus 11205 controls the drive of the energy treatment tool 11112 for, for example, tissue ablation, incision, and blood vessel sealing. In order to inflate the body cavity of the patient 11132 for securing a field of view for the endoscope 11100 and securing operation space for a surgeon, the pneumoperitoneum apparatus 11206 sends gas to the body cavity via the pneumoperitoneum tube 11111. A recorder 11207 is an apparatus capable of recording various pieces of information regarding surgery. A printer 11208 is an apparatus capable of printing various pieces of information regarding surgery in various formats such as text, an image, and a graph.

Note that the light source apparatus 11203, which supplies irradiation light at the time when the endoscope 11100 captures an image of a surgical site, can include, for example, an LED, a laser light source, or a white light source including a combination thereof. In a case where a combination of RGB laser light sources configures a white light source, the output intensity and output timing of each color (each wavelength) can be controlled with high precision. The light source apparatus 11203 thus can adjust white balance of a captured image. Furthermore, in the case, images corresponding to RGB can be captured in time division by applying laser light from each of RGB laser light sources to an observation target in time division and controlling the drive of an imaging element of the camera head 11102 in synchronization with the irradiation timing. According to the method, a color image can be obtained without providing a color filter in the imaging element.

Furthermore, the drive of the light source apparatus 11203 may be controlled so that the intensity of output light is changed every predetermined time. An image in a high dynamic range without a so-called black defect and halation can be generated by controlling the drive of the imaging element of the camera head 11102 in synchronization with the timing of change in the light intensity to acquire images in time division and combining the images.

Furthermore, the light source apparatus 11203 may be configured so as to supply light in a predetermined wavelength band, which can be used in special light observation. In the special light observation, for example, so-called narrow band imaging is performed. In the narrow band imaging, an image of a predetermined tissue such as a blood vessel in the surface layer of the mucous membrane is captured with high contrast by applying light in a band narrower than irradiation light (i.e., white light) at the time of an ordinary observation by using wavelength dependency of light absorption in a body tissue. Alternatively, in special light observation, fluorescence observation may be performed. In the fluorescence observation, an image is obtained by fluorescence generated by applying excitation light. In the fluorescence observation, for example, fluorescence from a body tissue can be observed by applying excitation light to the body tissue (autofluorescence observation). A fluorescent image can be obtained by locally injecting a reagent such as indocyanine green (ICG) and applying excitation light corresponding to the fluorescence wavelength of the reagent to the body tissue. The light source apparatus 11203 can be configured so as to supply narrowband light and/or excitation light, which can be used in such a special light observation.

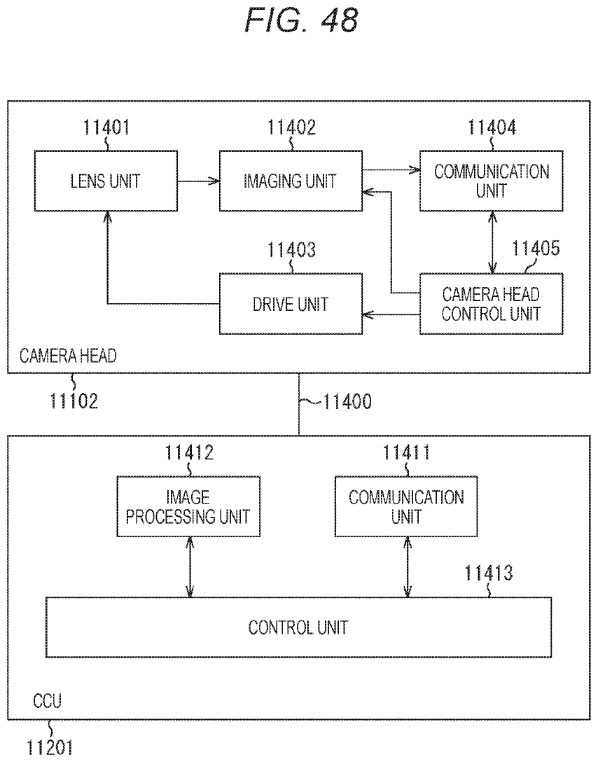

FIG. 48 is a block diagram illustrating one example of the functional configurations of the camera head 11102 and the CCU 11201 illustrated in FIG. 47.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are connected so as to communication with each other by a transmission cable 11400.

The lens unit 11401 is an optical system provided at a connection part with the lens barrel 11101. Observation light captured from the distal end of the lens barrel 11101 is guided to the camera head 11102, and is incident to the lens unit 11401. The lens unit 11401 is configured by combining a plurality of lenses including a zoom lens and a focus lens.

The imaging unit 11402 includes an imaging element. One (so-called single-plate type) imaging element or a plurality of (so-called multi-plate type) imaging elements may constitute the imaging unit 11402. In a case where the multi-plate type imaging unit 11402 is used, for example, each of imaging elements may generate image signals corresponding to each of RGB, and the image signals may be combined to obtain a color image. Alternatively, the imaging unit 11402 may include a pair of imaging elements, for acquiring image signals for a right eye and a left eye, which can be used in three-dimensional (3D) display. The 3D display enables the surgeon 11131 to more accurately grasp the depth of a biological tissue in a surgical site. Note that, in a case where the multi-plate type imaging unit 11402 is used, a plurality of lens units 11401 can be provided corresponding to each of the imaging elements.

Furthermore, the imaging unit 11402 is not necessarily provided in the camera head 11102. For example, the imaging unit 11402 may be provided inside the lens barrel 11101 immediately after an objective lens.

The drive unit 11403 includes an actuator, and moves a zoom lens and a focus lens of the lens unit 11401 by a predetermined distance along an optical axis under the control of the camera head control unit 11405. This enables the magnification and focus of a captured image obtained by the imaging unit 11402 to be appropriately adjusted.

The communication unit 11404 includes a communication apparatus for transmitting/receiving various types of information to/from the CCU 11201. The communication unit 11404 transmits an image signal obtained from the imaging unit 11402 as RAW data to the CCU 11201 via the transmission cable 11400.

Furthermore, the communication unit 11404 receives a control signal for controlling the drive of the camera head 11102 from the CCU 11201, and supplies the control signal to the camera head control unit 11405. The control signal includes information regarding an imaging condition such as, for example, information for specifying a frame rate of a captured image, information for specifying an exposure value at the time of imaging, and/or information for specifying a magnification and focus of the captured image.

Note that the above-described imaging conditions, such as the frame rate, exposure value, magnification, and focus, may be appropriately specified by a user, or may be automatically set by the control unit 11413 of the CCU 11201 on the basis of the acquired image signal. In the latter case, a so-called auto exposure (AE) function, auto focus (AF) function, and auto white balance (AWB) function are mounted in the endoscope 11100.

The camera head control unit 11405 controls the drive of the camera head 11102 on the basis of a control signal, from the CCU 11201, received via the communication unit 11404.

The communication unit 11411 includes a communication apparatus for transmitting/receiving various types of information to/from the camera head 11102. The communication unit 11411 receives an image signal transmitted via the transmission cable 11400 from the camera head 11102.

Furthermore, the communication unit 11411 transmits a control signal for controlling the drive of the camera head 11102 to the camera head 11102. The image signal and the control signal can be transmitted by, for example, electrical communication and optical communication.

The image processing unit 11412 performs various types of image processing on an image signal, which is RAW data, transmitted from the camera head 11102.

The control unit 11413 performs various controls related to imaging of, for example, a surgical site with the endoscope 11100 and display of the captured image obtained by imaging of, for example, the surgical site. For example, the control unit 11413 generates a control signal for controlling the drive of the camera head 11102.

Furthermore, the control unit 11413 causes the display 11202 to display a captured image in which, for example, a surgical site is reflected on the basis of the image signal on which image processing is performed by the image processing unit 11412. At this time, the control unit 11413 may recognize various objects in the captured image by using various image recognition techniques. For example, the control unit 11413 can recognize, for example, a surgical tool such as forceps, a specific biological site, bleeding, and mist at the time of using the energy treatment tool 11112 by detecting, for example, the shape and color of an edge of an object in the captured image. At the time of displaying the captured image on the display 11202, the control unit 11413 may superimpose and display various types of surgery support information on the image of the surgical site with reference to the recognition result. The superimposed and displayed surgery support information presented for the surgeon 11131 can reduce the burden on the surgeon 11131, and enables the surgeon 11131 to reliably proceed with a surgery.

The transmission cable 11400, which connects the camera head 11102 and the CCU 11201, includes an electrical signal cable that can be used in electrical signal communication, an optical fiber that can be used in optical communication, or a composite cable thereof.

Although, in the example illustrated here, communication is performed by wire with the transmission cable 11400, communication between the camera head 11102 and the CCU 11201 may be performed wirelessly.

One example of the endoscopic surgical system to which the technology according to the disclosure can be applied has been described above. The technology according to the disclosure can be applied to the imaging unit 11402 of the camera head 11102 among the above-described configurations. Specifically, the above-described imaging element 1 can be applied as the imaging unit 11402. The imaging unit 11402 to which the technology according to the disclosure is applied can reduce false signal output called a flare and ghost. The imaging unit 11402 thus enables a surgeon to reliably check a surgical site.

Note that, although an endoscopic surgical system has been described here in one example, the technology according to the disclosure may be applied to another system such as, for example, a microscope surgery system.

### 24. Example of Application to Moving Object

Moreover, the technology according to the disclosure can be embodied as an apparatus mounted in a moving object of one of types such as, for example, an automobile, an electrical vehicle, a hybrid electrical vehicle, a motorcycle, a bicycle, a personal mobility, an airplane, a drone, a ship, and a robot.

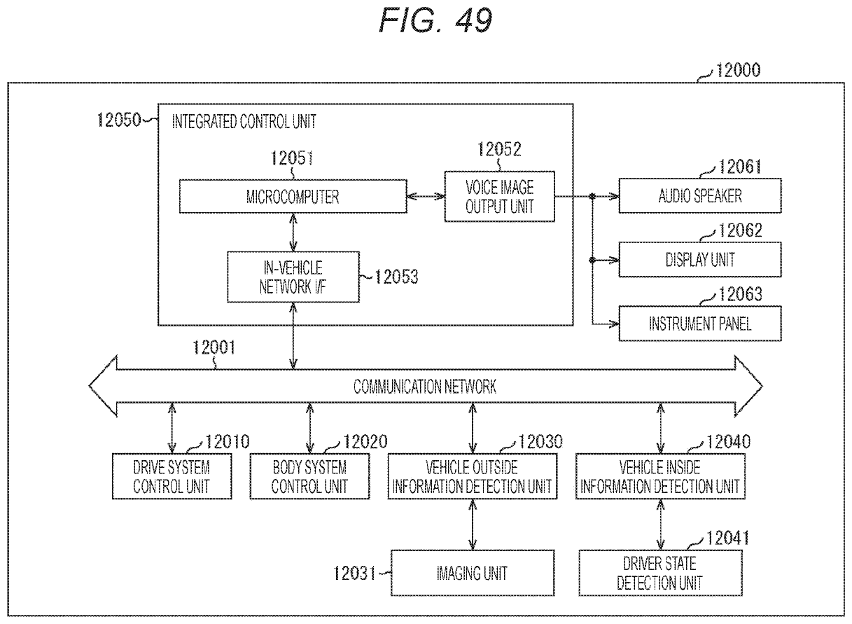

FIG. 49 is a block diagram illustrating a schematic configuration example of a vehicle control system, which is one example of a moving object control system to which the technology according to the disclosure can be applied.

A vehicle control system 12000 includes a plurality of electronic control units connected via a communication network 12001. In the example illustrated in FIG. 49, the vehicle control system 12000 includes a drive system control unit 12010, a body system control unit 12020, a vehicle outside information detection unit 12030, a vehicle inside information detection unit 12040, and an integrated control unit 12050. Furthermore, a microcomputer 12051, a voice image output unit 12052, and an in-vehicle network interface (I/F) 12053 are illustrated as functional configurations of the integrated control unit 12050.

The drive system control unit 12010 controls the operation of an apparatus related to a drive system of a vehicle in accordance with various programs. For example, the drive system control unit 12010 functions as a control apparatus for, for example, a driving force generation apparatus, a driving force transmission mechanism, a steering mechanism, and a braking apparatus. The driving force generation apparatus includes, for example, an internal combustion engine and a driving motor, and generates driving force for a vehicle. The driving force transmission mechanism transmits the driving force to a wheel. The steering mechanism adjusts the rudder angle of the vehicle. The braking apparatus generates braking force of the vehicle.

The body system control unit 12020 controls the operations of various apparatuses equipped in a vehicle body in accordance with various programs. For example, the body system control unit 12020 functions as a control apparatus for a keyless entry system, a smart key system, a power window apparatus, or various lamps. The lamps include, for example, a headlamp, a back lamp, a brake lamp, a blinker, and a fog lamp. In the case, a radio wave transmitted from a portable device substituted for a key or signals of various switches can be input in the body system control unit 12020. The body system control unit 12020 receives the input of a radio wave or a signal, and controls, for example, a door lock apparatus, a power window apparatus, and a lamp of a vehicle.

The vehicle outside information detection unit 12030 detects information regarding the outside of a vehicle mounted with the vehicle control system 12000. For example, an imaging unit 12031 is connected to the vehicle outside information detection unit 12030. The vehicle outside information detection unit 12030 causes the imaging unit 12031 to capture an image outside the vehicle, and receives the captured image. The vehicle outside information detection unit 12030 may perform object detection processing or distance detection processing for a person, a vehicle, an obstacle, a sign, or a character on a road surface on the basis of the received image.

The imaging unit 12031 is an optical sensor that receives light and outputs an electrical signal corresponding to an amount of received light. The imaging unit 12031 can output an electrical signal as an image, or can also output information related to distance measurement. Furthermore, light received by the imaging unit 12031 may be visible light or invisible light such as infrared rays.

The vehicle inside information detection unit 12040 detects information regarding the inside of a vehicle. For example, a driver state detection unit 12041 is connected to the vehicle inside information detection unit 12040. The driver state detection unit 12041 detects the state of a driver. The driver state detection unit 12041 includes, for example, a camera that images a driver. The vehicle inside information detection unit 12040 may calculate the degree of fatigue or concentration of the driver, or may determine whether or not the driver is asleep on the basis of detection information input from the driver state detection unit 12041.

The microcomputer 12051 can calculate a control target value of the driving force generation apparatus, the steering mechanism, or the braking apparatus on the basis of information, regarding the inside/outside of a vehicle, acquired by the vehicle outside information detection unit 12030 or the vehicle inside information detection unit 12040, and output a control command to the drive system control unit 12010. For example, the microcomputer 12051 can perform cooperative control for achieving a function of an advanced driver assistance system (ADAS) including, for example, avoidance of vehicle collision or shock mitigation, following traveling based on a distance between vehicles, vehicle speed maintenance traveling, warning against vehicle collision, or warning against lane departure of a vehicle.

Furthermore, the microcomputer 12051 can perform cooperative control for, for example, automatic driving by controlling the driving force generation apparatus, the steering mechanism, the braking apparatus, or the like on the basis of information, regarding the surroundings of a vehicle, acquired at the vehicle outside information detection unit 12030 or the vehicle inside information detection unit 12040. In the automatic driving, autonomous traveling is performed without depending on an operation of a driver.

Furthermore, the microcomputer 12051 can output a control command to the body system control unit 12020 on the basis of information, regarding the outside of a vehicle, acquired at the vehicle outside information detection unit 12030. For example, the microcomputer 12051 can control a headlamp in accordance with the position of a preceding car or an oncoming car detected at the vehicle outside information detection unit 12030, and perform cooperative control for preventing glare such as switching from high beam to low beam.

The voice image output unit 12052 transmits an output signal of at least one of sound or image to an output apparatus capable of visually or audibly notifying a vehicle occupant or vehicle outside of information. In the example of FIG. 49, an audio speaker 12061, a display unit 12062, and an instrument panel 12063 are illustrated as output apparatuses. For example, the display unit 12062 may include at least one of an on-board display or a head-up display.

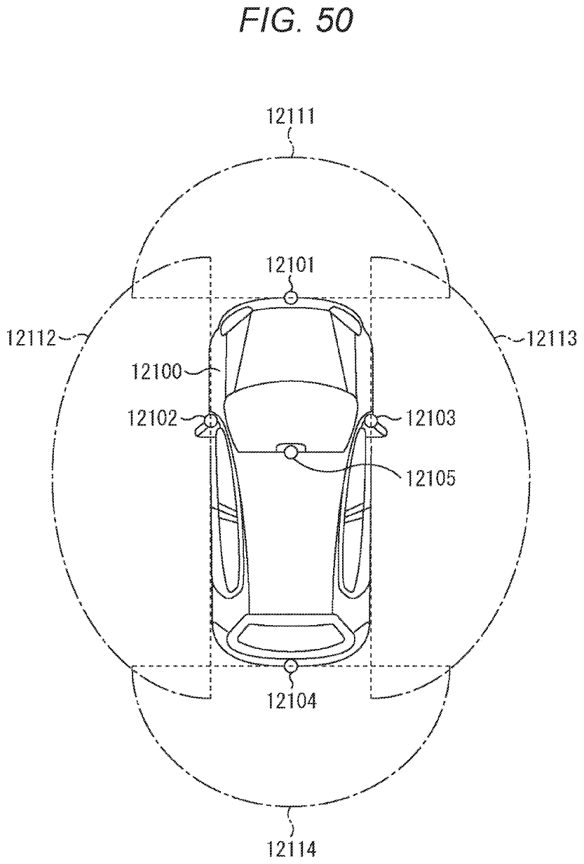

FIG. 50 illustrates an example of an installation position of the imaging unit 12031.

In FIG. 50, a vehicle 12100 includes imaging units 12101, 12102, 12103, 12104, and 12105 as the imaging unit 12031.

The imaging units 12101, 12102, 12103, 12104, and 12105 are provided at a position of, for example, a front nose, a side mirror, a rear bumper, a back door, an upper part of a windshield in the vehicle interior, and the like of the vehicle 12100. The imaging unit 12101 provided in the front nose and the imaging unit 12105 provided in the upper part of the windshield in the vehicle interior mainly acquire an image in front of the vehicle 12100. The imaging units 12102 and 12103 provided in the side mirrors mainly acquire an image on the lateral side of the vehicle 12100. The imaging unit 12104 provided in the rear bumper or the back door mainly acquires an image behind the vehicle 12100. An image acquired by the imaging units 12101 and 12105 are mainly used for detecting, for example, a preceding vehicle, a pedestrian, an obstacle, a traffic light, a traffic sign, or a lane.

Note that FIG. 50 illustrates one example of the image capturing ranges of the imaging units 12101 to 12104. An imaging range 12111 indicates the imaging range of the imaging unit 12101 provided at the front nose. The imaging ranges 12112 and 12113 indicate the imaging ranges of the imaging units 12102 and 12103 provided at the side mirrors. The imaging range 12114 indicates the imaging range of the imaging unit 12104 provided at the rear bumper or the back door. For example, an overhead view in which the vehicle 12100 is seen from above can be obtained by superimposing pieces of data of images captured by the imaging units 12101 to 12104.

At least one of the imaging units 12101 to 12104 may have a function of acquiring distance information. For example, at least one of the imaging units 12101 to 12104 may be a stereo camera including a plurality of imaging elements, or may be an imaging element having a pixel for phase difference detection.

For example, the microcomputer 12051 can extract a solid object as a preceding car by determining each distance to the solid object in the imaging ranges 12111 and 12114 and temporal change in the distance (relative speed with respect to the vehicle 12100) on the basis of the distance information obtained from the imaging units 12101 to 12104. In particular, the solid object is closest to the vehicle 12100 in the advancing route, and travels at a predetermined speed (e.g., 0 km/h or more) in substantially the same direction as the vehicle 12100. Moreover, the microcomputer 12051 can set a distance between vehicles to be preliminarily secured in front of the preceding car, and perform, for example, automatic brake control (including following stop control) and automatic acceleration control (following start control). In this way, cooperative control for, for example, automatic driving in which traveling is autonomously performed without depending on an operation of a driver can be performed.

For example, the microcomputer 12051 can classify solid object data regarding a solid object into a two-wheel vehicle, an ordinary vehicle, a large vehicle, a pedestrian, and other solid objects such as a utility pole and extract the data on the basis of distance information obtained from the imaging units 12101 to 12104. The microcomputer 12051 can then use the data for automatic avoidance of an obstacle. For example, the microcomputer 12051 identifies obstacles around the vehicle 12100, and divides the obstacles into obstacles that a driver of the vehicle 12100 can see and obstacles difficult to be seen. Then, the microcomputer 12051 determines a collision risk indicating the degree of risk of collision against each obstacle. In a situation where the collision risk is at a set value or more and collision may occur, the microcomputer 12051 outputs an alarm to the driver via the audio speaker 12061 or the display unit 12062, and performs forced deceleration or avoidance steering via the drive system control unit 12010. In such a way, the microcomputer 12051 can support driving to avoid a collision.

At least one of the imaging units 12101 to 12104 may be an infrared camera that detects infrared rays. For example, the microcomputer 12051 can recognize a pedestrian by determining whether or not a captured image from the imaging units 12101 to 12104 contains the pedestrian. Such pedestrian recognition is performed in, for example, an extraction procedure and a determination procedure. In the extraction procedure, feature points in captured images from the imaging units 12101 to 12104 serving as infrared cameras are extracted. In the determination procedure, whether or not an object is a pedestrian is determined by performing pattern matching processing on a series of feature points indicating the outline of the object. In a case where the microcomputer 12051 determines that the captured images from the imaging units 12101 to 12104 contain a pedestrian and recognizes the pedestrian, the voice image output unit 12052 controls the display unit 12062 so that a quadrangular outline for emphasis is superimposed and displayed on the recognized pedestrian. Furthermore, the voice image output unit 12052 may control the display unit 12062 so that, for example, an icon indicating a pedestrian is displayed at a desired position.

One example of the vehicle control system to which the technology according to the disclosure can be applied has been described above. The technology according to the disclosure can be applied to the imaging unit 12031 among the above-described configurations. Specifically, the above-described imaging element 1 can be applied as the imaging unit 12031. The imaging unit 12031 to which the technology according to the disclosure is applied can reduce false signal output called a flare and ghost. The imaging unit 12031 can thus obtain a captured image easier to see, and contribute to improvement of safety of a vehicle.

Note that the effects described in the specification are merely examples and are not limitative, and effects other than those described in the specification may be exhibited.

Note that the present technology can also have the configurations as follows.

(1)

An imaging element including:

a semiconductor substrate including a photoelectric conversion unit for each pixel, the photoelectric conversion unit photoelectrically converting incident light;

a color filter layer that is formed on the semiconductor substrate and that passes the incident light of a predetermined wavelength;

a light-shielding wall that is formed at a pixel boundary on the semiconductor substrate so as to have a height greater than a height of the color filter layer; and

a protective substrate that is disposed via a seal resin and that protects an upper-surface side of the color filter layer.

(2)

The imaging element according to (1), further including

an on-chip lens above the color filter layer,

in which the light-shielding wall is formed so as to have a same height as a height of the on-chip lens or a height greater than the height of the on-chip lens.

(3)

The imaging element according to (1) or (2),

in which the light-shielding wall is formed up to a height that reaches the seal resin.

(4)

The imaging element according to (1) or (2),

in which the light-shielding wall is formed up to a height that reaches the protective substrate.

(5)

The imaging element according to any one of (1) to (4),

in which the light-shielding wall is formed so as to be thinner in cross section toward an upper part.

(6)

The imaging element according to any one of (2) to (5), further including

a light-transmitting layer between the on-chip lens and the seal resin, the light-transmitting layer transmitting the incident light,

in which the light-transmitting layer has a refractive index lower than a refractive index of the on-chip lens.

(7)

The imaging element according to any one of (1) to (5), further including

a light-transmitting layer between the color filter layer and the seal resin, the light-transmitting layer transmitting the incident light,

in which the light-transmitting layer has a refractive index between a refractive index of the protective substrate and a refractive index of the color filter layer.

(8)

The imaging element according to any one of (1) to (7),

in which the light-shielding wall has a height at which the incident light having an incidence angle equal to or greater than a predetermined incidence angle is cut.

(9)

The imaging element according to (8), further including

an on-chip lens above the color filter layer,

in which a protrusion amount of the light-shielding wall is calculated in (pixel size/2)×tan (90−angle of the incident light desired to be cut), where a height of the light-shielding wall on an upper side of the on-chip lens is defined as the protrusion amount.

(10)

The imaging element according to any one of (1) to (9), further including

a pixel whose light-shielding wall is formed in an uneven shape in plan view.

(11)

The imaging element according to (10),

in which an R pixel is formed in the uneven shape.

(12)

The imaging element according to (10),

in which all pixels are formed in the uneven shape.

(13)

The imaging element according to any one of (10) to (12),

in which the uneven shape is a sawtooth shape.

(14)

The imaging element according to any one of (1) to (13),

in which the light-shielding wall has a wavy shape in cross-sectional view.

(15)

The imaging element according to any one of (1) to (14),

in which the light-shielding wall is formed by one or both of light absorbing material and metal material.

(16)

The imaging element according to (15),

in which the light-shielding wall is formed by both of light absorbing material and metal material, and

a lower part of the light-shielding wall is formed by the metal material, and an upper part is formed by the light absorbing material.

(17)

The imaging element according to (15) or (16),

in which the light absorbing material includes carbon black, and

the metal material includes tungsten.

(18)

A method of manufacturing an imaging element, including:

forming a color filter layer that passes incident light of a predetermined wavelength on a semiconductor substrate including a photoelectric conversion unit for each pixel, the photoelectric conversion unit photoelectrically converting the incident light;

forming a light-shielding wall having a height greater than a height of the color filter layer at a pixel boundary on the semiconductor substrate; and

bonding a protective substrate on an upper side of the color filter layer via a seal resin.

(19)

An electronic appliance including

an imaging element that includes:

a semiconductor substrate including a photoelectric conversion unit for each pixel, the photoelectric conversion unit photoelectrically converting incident light;

a color filter layer that is formed on the semiconductor substrate and that passes the incident light of a predetermined wavelength;

a light-shielding wall that is formed at a pixel boundary on the semiconductor substrate so as to have a height greater than a height of the color filter layer; and

a protective substrate that is disposed via a seal resin and that protects an upper-surface side of the color filter layer.

### REFERENCE SIGNS LIST

1 Imaging element
11 Imaging substrate
PD Photodiode
21 Semiconductor substrate
22 Photoelectric conversion region
23 On-chip lens (OCL)
24 Flattening film
25 Glass seal resin
26 Cover glass
50 Inter-pixel light-shielding film
51 Color filter layer (CF layer)
(52A to 52J) Light-shielding wall
300 Imaging apparatus
302 Solid-state imaging apparatus

1. An imaging element comprising:
a semiconductor substrate including a photoelectric conversion unit for each pixel, the photoelectric conversion unit photoelectrically converting incident light;
a color filter layer that is formed on the semiconductor substrate and that passes the incident light of a predetermined wavelength;
a light-shielding wall that is formed at a pixel boundary on the semiconductor substrate so as to have a height greater than a height of the color filter layer; and
a protective substrate that is disposed via a seal resin and that protects an upper-surface side of the color filter layer.

2. The imaging element according to claim 1, further comprising
an on-chip lens above the color filter layer,
wherein the light-shielding wall is formed so as to have a same height as a height of the on-chip lens or a height greater than the height of the on-chip lens.

3. The imaging element according to claim 1,
wherein the light-shielding wall is formed up to a height that reaches the seal resin.

4. The imaging element according to claim 1,
wherein the light-shielding wall is formed up to a height that reaches the protective substrate.

5. The imaging element according to claim 1,
wherein the light-shielding wall is formed so as to be thinner in cross section toward an upper part.

6. The imaging element according to claim 2, further comprising
a light-transmitting layer between the on-chip lens and the seal resin, the light-transmitting layer transmitting the incident light,
wherein the light-transmitting layer has a refractive index lower than a refractive index of the on-chip lens.

7. The imaging element according to claim 1, further comprising
a light-transmitting layer between the color filter layer and the seal resin, the light-transmitting layer transmitting the incident light,
wherein the light-transmitting layer has a refractive index between a refractive index of the protective substrate and a refractive index of the color filter layer.

8. The imaging element according to claim 1,
wherein the light-shielding wall has a height at which the incident light having an incidence angle equal to or greater than a predetermined incidence angle is cut.

9. The imaging element according to claim 8, further comprising
an on-chip lens above the color filter layer,
wherein a protrusion amount of the light-shielding wall is calculated in (pixel size/2)×tan (90−angle of the incident light desired to be cut), where a height of the light-shielding wall on an upper side of the on-chip lens is defined as the protrusion amount.

10. The imaging element according to claim 1, further comprising
a pixel whose light-shielding wall is formed in an uneven shape in plan view.

11. The imaging element according to claim 10,
wherein an R pixel is formed in the uneven shape.

12. The imaging element according to claim 10,
wherein all pixels are formed in the uneven shape.

13. The imaging element according to claim 10,
wherein the uneven shape is a sawtooth shape.

14. The imaging element according to claim 1,
wherein the light-shielding wall has a wavy shape in cross-sectional view.

15. The imaging element according to claim 1,
wherein the light-shielding wall is formed by one or both of light absorbing material and metal material.

16. The imaging element according to claim 15,
wherein the light-shielding wall is formed by both of light absorbing material and metal material, and
a lower part of the light-shielding wall is formed by the metal material, and an upper part is formed by the light absorbing material.

17. The imaging element according to claim 15,
wherein the light absorbing material includes carbon black, and
the metal material includes tungsten.

18. A method of manufacturing an imaging element, comprising:
forming a color filter layer that passes incident light of a predetermined wavelength on a semiconductor substrate including a photoelectric conversion unit for each pixel, the photoelectric conversion unit photoelectrically converting the incident light;
forming a light-shielding wall having a height greater than a height of the color filter layer at a pixel boundary on the semiconductor substrate; and
bonding a protective substrate on an upper side of the color filter layer via a seal resin.

19. An electronic appliance comprising
an imaging element that includes:
a semiconductor substrate including a photoelectric conversion unit for each pixel, the photoelectric conversion unit photoelectrically converting incident light;
a color filter layer that is formed on the semiconductor substrate and that passes the incident light of a predetermined wavelength;
a light-shielding wall that is formed at a pixel boundary on the semiconductor substrate so as to have a height greater than a height of the color filter layer; and
a protective substrate that is disposed via a seal resin and that protects an upper-surface side of the color filter layer.
